(19) United States
(12) Patent Application Publication
(10) Pub. No.: US 2026/0282903 A1
(43) Pub. Date: Sep. 17, 2026

(54) POWER ELECTRONICS COMPONENT WITH COOLING AND A POWER CONVERTER

(71) Applicant: TRUMPF Hüttinger GmbH + Co. KG, Freiburg (DE)

(72) Inventors: Guido Dieter Hodapp, Emmendingen (DE); Thilo Vethake, Roosevelt, NJ (US)

(21) Appl. No.: 19/672,789

(22) Filed: May 11, 2026

Related U.S. Application Data
(63) Continuation of application No. PCT/EP2024/082608, filed on Nov. 15, 2024.

(30) Foreign Application Priority Data
Nov. 15, 2023 (DE) 10 2023 131 883.7
Nov. 20, 2023 (DE) 10 2023 132 302.4

(51) Int. Cl. H10W 40/20; H01F 27/28; H10W 40/00

(52) U.S. Cl. CPC H10W 40/237; H01F 27/2804; H10W 40/037; H10W 40/233; H01F 2027/2809

(57) ABSTRACT

A power electronics component includes an electrically insulating substrate including a top-side and bottom-side metallization layer. The top-side metallization layer is divided into at least three electrically isolated regions of a conductor structure. The component also includes a semiconductor assembly mounted on the substrate, including two semiconductor components connected in series, each including a first connection, thermally and electrically connected to a region of the conductor structure, and a second connection, electrically connected to a second connection surface of another semiconductor component and/or to one of the regions of the conductor structure. The component also includes a heat sink arranged on the substrate. A first side facing the substrate is thermally connected to the bottom-side metallization layer which faces away from the semiconductor assembly. The heat sink is monolithically constructed, is fixedly connected to the bottom-side metallization layer, and includes a cooling channel for guiding a cooling flow.

### CROSS REFERENCE TO RELATED APPLICATIONS

This application is a continuation of International Application No. PCT/EP2024/082608 (WO 2025/104320 A1), filed on Nov. 15, 2024, and claims benefit to German Patent Application No. DE 10 2023 131 883.7, filed on Nov. 15, 2023 and to German Patent Application No. DE 10 2023 132 302.4, filed on Nov. 20, 2023. The aforementioned applications are hereby incorporated by reference herein.

### FIELD

The present disclosure relates to a power electronics component with cooling. Furthermore, the present disclosure relates to a method for joining a power electronics component.

The present disclosure also relates to an electric power converter for an industrial process assembly, preferably a plasma process assembly or heating assembly, having in particular an RF amplifier arrangement. This RF amplifier arrangement has a previously mentioned power electronics component and is designed to generate an RF output power, in particular for plasma excitation purposes such as plasma coating processes, preferably for the production of semiconductor structures.

### BACKGROUND

There are particular challenges for cooling in the field of electric power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating, or plasma torches. This can be a process for generating radiation, such as microwave radiation, X-rays or particle accelerators. A feature common to all of these processes is that they are designed to generate and accelerate charged atomic particles or subatomic particles in a gas and/or plasma environment or liquid. Another feature common to all of these processes is that they have a high power consumption which is in the range of 1 kW or more, in particular 10 kW or more, preferably 100 kW or more. In this context, frequencies ≥20 kHz, preferably ≥200 kHz, in particular ≥2 MHz are generated internally or for external applications for the aforementioned power range. Many of these processes also have a very high requirement for the stability of the power supply because the processes are highly complex, such as semiconductor production using plasma processes and/or heating by electromagnetic fields. Typically, power is converted from a mains frequency, which is in the range of approximately 50 Hz to 60 Hz, to different frequencies, which can be in the above-mentioned range. Conversion to direct-current power, also called DC power, is also conceivable. Also when converting to DC power, a frequency in the above-mentioned range is often generated internally for the power signal, which is then rectified again according to the voltage, current and power requirements. A plurality of electronic components and assemblies is required for this conversion of electric power into other frequencies, but in particular power semiconductor components, such as transistors or diodes, in particular PIN diodes, such as for switching RF power between different paths, or a combination of a transistor with a diode designed for currents ≥10 A and voltages ≥400 V. These electronic components and assemblies generate waste heat during operation. The waste heat often occurs over a very limited area of just a few mm², for example ≤8 mm². It is a particular challenge to dissipate this waste heat in order to protect the components and/or assemblies from destruction due to overheating. Often, very large and material-intensive heat sinks are used for this purpose, the production of which is very expensive.

In the prior art, the heat is dissipated by cooling using a cooling plate. When cooling with such a conventional cooling plate, the heat transfer from the electric component, which may have a copper layer, to the cooling medium is achieved by applying a material, such as thermal paste, to the thermal interface, thereby dissipating the generated heat. In this regard, such heat interface material is disadvantageous. Firstly, it constitutes another heat transfer with thermal resistance, and secondly, it is subject to wear, which gradually degrades its effectiveness during operation. The surface area of the cooling plate is also increased, or the number and performance of the components are reduced, in order to dissipate a larger amount of heat. Neither option proves sufficient. Since the installation space in the housing of such a power supply is limited, the cooling surface cannot be expanded indefinitely. Reducing the performance of individual components is also not a viable solution. Overall, inadequate cooling of the electric components results in costs.

A particularly challenging field is a process for plasma excitation purposes, in particular plasma processing, such as coating, e.g., PVD, CVD, or etching. Such processes are used in the production of semiconductors such as microprocessor components and/or memory chips. The requirements for reliability, durability and process repeatability are particularly high here. At the same time, the required power output is also very high. In addition, the required output modulations, such as for modern electric power converters with an RF amplifier arrangement or pulsed high-voltage supplies with pulse shaping, have increased steadily in recent times. For example, one requirement for RF amplifier arrangements can be the ability to be pulsable at several different power levels, which is referred to as Multi-Level Pulsing (MLP). A further requirement for RF amplifier arrangements can be, for example, the ability to be adjustable in frequency and thus be able to react quickly to load changes, for example, which is referred to as Auto-Frequency-Tuning (AFT). A further requirement can be, for example, the ability to provide a very high DC voltage, for example greater than or equal to 2 kV, in particular greater than or equal to 7 kV pulsed, with pulse frequencies greater than or equal to 1 kHz, in particular greater than or equal to 10 kHz, particularly preferably greater than or equal to 200 kHz. With all these requirements, the demands on power semiconductor components that are installed in the RF amplifier arrangement and used to generate the RF power also increase. In particular, the requirement for these components to convert power that cannot be supplied to the load in certain states into heat is also increasing. These losses, which are converted into heat, can be ≥500 W in some applications, in particular ≥1 kW. This heat must be dissipated from the power semiconductor components, otherwise they will be destroyed by overheating.

### SUMMARY

In an embodiment, the present disclosure provides a power electronics component for an electric power converter for an industrial process assembly designed to supply a load. The component includes an electrically insulating substrate including a top-side metallization layer on a top side and a bottom-side metallization layer on a bottom side. The top-side metallization layer is divided into at least three electrically isolated regions of a conductor structure. The component also includes a semiconductor assembly mounted on the substrate, including at least two semiconductor components connected in series, at least one of which is a controllable power semiconductor component. The two semiconductor components connected in series each includes at least one first connection configured as a collector connection surface or source connection surface, thermally and electrically connected to at least one first region of the conductor structure, and at least one second connection configured as an emitter connection surface or drain connection surface, electrically connected via a plurality of connecting lines to a second connection surface of another semiconductor component and/or to one of the regions of the conductor structure. The component also includes a heat sink arranged on the substrate. A first side facing the substrate is thermally connected to the bottom-side metallization layer of the substrate, which bottom-side metallization layer faces away from the semiconductor assembly. The heat sink is monolithically constructed, is fixedly connected to the bottom-side metallization layer, and includes a cooling channel for guiding a cooling flow.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an industrial process assembly with an electric power converter with a first embodiment of a power electronics component;

FIG. 1a shows a first embodiment of a power electronics component;

FIG. 1b shows a circuit diagram of an embodiment of a semiconductor assembly designed as a semiconductor switching unit;

FIG. 1c shows a detailed view of a power electronics component from FIG. 1a;

FIG. 1d shows a circuit diagram of an embodiment of a semiconductor assembly designed as an AC converter assembly;

FIG. 2 shows an electronics assembly as part of a second embodiment of a power electronics component;

FIG. 3 shows a further embodiment of an electronics assembly as part of a fourth embodiment of a power electronics component;

FIG. 4 shows the connection surfaces of an IGBT;

FIG. 5 shows a further embodiment of a power electronics component;

FIG. 6 shows an embodiment of a power electronics component in an oblique view;

FIG. 6a shows an electric power converter in an industrial process assembly, preferably a plasma process assembly or a heating assembly;

FIG. 7 shows a further embodiment of a power electronics component;

FIG. 8 shows a third embodiment of a power electronics component;

FIG. 9 shows a further embodiment of a power electronics component;

FIG. 10 shows a first possibility for guiding a control connection of a semiconductor component out of the power electronics component towards the side;

FIG. 11 shows a second possibility for guiding a control connection of a semiconductor component out of the power electronics component towards the side;

FIG. 12 shows a third possibility for guiding a control connection of a semiconductor component out of the power electronics component; and

FIG. 12a shows an electric power converter in an industrial process assembly, preferably a plasma process assembly or a heating assembly.

### DETAILED DESCRIPTION

Aspects of the present disclosure provide a power electronics component and a method for joining a power electronics component which allow for an improved dissipation of the heat generated during operation of power components. Aspects of the present disclosure also provide an electric power converter for an industrial process assembly which allows for an improved dissipation of the heat generated during the operation of power components.

In an aspect, the power electronics component for an electric power converter for an industrial process assembly is designed to supply a load, preferably a plasma process or heating process. For this purpose, the power electronics component has the following: an electrically insulating first substrate which has a top-side metallization layer on its top side and a bottom-side metallization layer on its bottom side, wherein the top-side metallization layer is divided into at least three electrically isolated regions of a conductor structure, a semiconductor assembly which is mounted on the first substrate and which has: at least two semiconductor components connected in series, e.g., one or more transistors, in particular one or more IGBTs, or one or more diodes, in particular PIN diodes. Of the two semiconductor components connected in series, at least one is a controllable power semiconductor component, e.g., a transistor or a PIN diode. In this context, the two semiconductor components connected in series have the following: in each case at least one first connection, in particular designed as a collector connection surface or source connection surface, which is thermally and electrically connected to at least one first region of the conductor structure, in each case at least one second connection, in particular designed as an emitter connection surface or drain connection surface, which is electrically connected via a plurality of connecting lines, in particular designed as bonding wires, to a second connection surface of another semiconductor component and/or to one of the regions of the conductor structure, a first heat sink arranged on the first substrate, the first side of which heat sink facing the first substrate is thermally connected to the bottom-side metallization layer of the first substrate, which bottom-side metallization layer faces away from the semiconductor assembly, wherein the heat sink is monolithically constructed and is fixedly connected to the bottom-side metallization layer and has a first cooling channel for guiding a cooling flow.

The thermal resistance can thus be significantly reduced. This allows the semiconductor assembly to be cooled very effectively. The heat sink can be designed to be many times smaller.

In one aspect of the development, the semiconductor components are designed as bare die semiconductor components and are thermally and electrically connected directly with their first connection to one of the regions of the conductor structure.

This allows the thermal resistance to be reduced even further. This allows the semiconductor assembly to be cooled even more effectively.

In one aspect of the development, the three regions of the conductor structure are arranged next to one another in series.

In one aspect of the development, two semiconductor components connected in series are arranged on at least two of the three regions of the conductor structure.

In one aspect of the development, a third region of the conductor structure is free of semiconductor components and, in particular, only has contacting connections.

In one aspect of the development, the third region of the conductor structure is arranged between the other two regions of the conductor structure.

In one aspect of the development, the power electronics component, in particular the semiconductor assembly, has the following: an AC converter assembly, having two DC voltage connections and two AC voltage connections, wherein the AC converter assembly is designed to convert a DC voltage or DC current into an AC voltage or AC current.

In particular, the AC converter assembly can, in this context, be designed to generate an RF output power in the range of 300 W or more, 1 kW or more, and in particular 2 kW or more, at frequencies of ≥20 kHz, preferably ≥200 kHz, and in particular ≥2 MHz.

An aspect includes a push-pull amplifier. This can have a bridge circuit, in particular a full bridge circuit.

Multiple AC converter assemblies of this type can be provided in one electric power converter and thus the electric power converter can provide output powers in the range of 1 kW or more, in particular 10 kW or more, preferably 100 kW or more.

In one aspect of the development, the component, in particular the semiconductor assembly, particularly preferably the AC converter assembly, has the following: a semiconductor switching unit, having two transistors, wherein the transistors are electrically connected to one another at at least one power terminal.

In one aspect of the development, the power electronics component, in particular the semiconductor assembly, particularly preferably the AC converter assembly, has the following: one, in particular two, or particularly preferably four identical semiconductor switching units, each having a control connection and two power terminals. The power terminals are preferably designed as a positive connection point and a negative connection point.

In one aspect of the development, the power electronics component, in particular the semiconductor assembly, particularly preferably the AC converter assembly, has the following: an intermediate circuit capacitor, which is, in particular, arranged very close to the semiconductor components, in particular very close to the power terminals of the transistors, preferably with connecting leads having a length ≤20 mm, particularly preferably ≤10 mm.

In one aspect of the development, the positive connection point is designed as one of the regions of the conductor structure.

In one aspect of the development, the negative connection point is designed as one of the regions of the conductor structure.

In one aspect of the development, the common connection point is designed as one of the regions of the conductor structure, in particular as one of the regions located between two other regions of the conductor structure.

In one aspect of the development, the power electronics component, in particular the semiconductor assembly, particularly preferably the AC converter assembly, has the following: a positive contact connection device and a negative contact connection device, in each case designed for contacting a connection point on a printed circuit board or a mechanical connecting line, such as a copper line.

In one aspect of the development, the positive contact connection device is directly electrically connected to one of the regions of the conductor structure, in particular to the positive connection point. In this regard, this connection is preferably produced by means of ultrasonic welding.

In one aspect of the development, the negative contact connection device is directly electrically connected to one of the regions of the conductor structure, in particular to the negative connection point. In this regard, this connection is preferably produced by means of ultrasonic welding.

In one aspect of the development, multiple transistors are electrically connected in parallel at their power terminals.

In one aspect of the development, at least one transistor is connected in series with a series diode arrangement, in particular having multiple series diodes connected in parallel, wherein one, multiple or in particular all series diodes are designed as Schottky diodes.

In one aspect of the development, a free-wheeling diode is connected electrically parallel with the power terminals of at least one of the transistors.

In one aspect of the development, several of the semiconductor switching units are arranged on a heat sink.

In one aspect of the development, the power electronics component further has the following: an electrically insulating additional substrate which has a metallization layer on each of its top and bottom sides, wherein the additional substrate is mounted on the second side of the first heat sink opposite the first side, and wherein the second side of the first heat sink is thermally connected to the metallization layer of the additional substrate facing the first heat sink.

In one aspect of the development, one or more semiconductor switching units are arranged on a top side of the heat sink and one or more further semiconductor switching units can be arranged on a bottom side of the heat sink.

In this manner, for example, a half bridge or full bridge can be cooled very effectively by a heat sink.

In one aspect, the power electronics component has a semiconductor assembly and an electrically insulating first substrate, on which the semiconductor assembly is mounted and which has a metallization layer on each of its top and bottom sides, wherein at least one connection of the semiconductor assembly is thermally and electrically connected to at least one region of the metallization layer of the first substrate facing the semiconductor assembly. In addition, the power electronics component comprises a first heat sink, the first side of which heat sink facing the first substrate is thermally and electrically connected to the metallization layer of the first substrate facing away from the semiconductor assembly. Furthermore, the power electronics component comprises an electrically insulating additional substrate which has a metallization layer on each of its top and bottom sides, wherein the additional substrate is mounted on the second side of the first heat sink opposite the first side, and wherein the second side of the first heat sink is thermally, and in particular also electrically, connected to the metallization layer of the additional substrate facing the first heat sink. In the following, the metallization layer is also referred to simply as “metallization” for short.

In the power electronics component according to this solution, the bottom side of a semiconductor assembly is cooled. For this purpose, the semiconductor assembly is thermally and electrically connected to the metallization of a first substrate facing the semiconductor assembly. A thermal and electric connection to the first heat sink is formed via the metallization of the first substrate facing away from the semiconductor assembly. The heat generated on the side of the semiconductor assembly can therefore efficiently reach the first heat sink via the metallization layers of the first substrate and be dissipated there. The side of the heat sink facing away from the semiconductor assembly is connected to an additional substrate. For this purpose, the first heat sink is thermally, and in particular also electrically, connected to the metallization of the additional substrate facing the heat sink. The first heat sink is therefore connected to the first substrate on its top side and to the additional substrate on its bottom side. This sandwich arrangement leads to a mechanically stable component. A further advantage is that further assemblies and components can be accommodated on the additional substrate, whose heat generated during operation can also be dissipated via the first heat sink. In particular, control circuits that generate the control signals required to operate power components, for example, can be considered here. However, the use of the additional substrate is not limited to control circuits. Rather, the additional substrate can be used for any type of components and assemblies.

In a further aspect, a method for joining a power electronics component is disclosed, wherein the method has the following steps: arranging a top-side metallization layer on a top side of an electrically insulating first substrate, wherein the top-side metallization layer is divided into at least three electrically isolated regions of a conductor structure, arranging a bottom-side metallization layer on the bottom side of the first substrate, arranging a semiconductor assembly on the first substrate, wherein the semiconductor assembly has the following: at least two semiconductor components connected in series, e.g., one or more transistors, in particular one or more IGBTs, or one or more diodes, in particular PIN diodes, at least one of which is a controllable power semiconductor component, e.g., a transistor or a PIN diode, establishing at least one thermal and electric connection between at least one connection of the semiconductor assembly, in particular of the two semiconductor components connected in series, and at least a first region of the top-side metallization layer of the first substrate facing the semiconductor assembly, establishing at least one electric connecting line from a second connection of the semiconductor assembly, in particular of the two semiconductor components connected in series, in particular designed as bonding wires, to at least one second connection surface of another semiconductor component or to one of the regions of the conductor structure, constructing a first monolithically constructed heat sink with a first cooling channel for guiding a cooling flow, arranging the first monolithically constructed heat sink on the first substrate, and in the process, establishing a thermal and electric connection between a first side of the first heat sink facing the first substrate and the bottom-side metallization layer of the first substrate facing away from the semiconductor assembly.

This allows the thermal resistance to be reduced. This allows the semiconductor assembly to be cooled very effectively.

In one aspect, the method has the following further method step: arranging a positive contact connection device at a region of the conductor structure with a direct electric connection to the region of the conductor structure, in particular by means of ultrasonic welding.

This allows the thermal resistance to be reduced even further. This allows the semiconductor assembly to be cooled even more effectively.

In one aspect, the method has the following further method step: arranging a negative contact connection device at a region of the conductor structure with a direct electric connection to the region of the conductor structure, in particular by means of ultrasonic welding.

This allows the thermal resistance to be reduced even further. This allows the semiconductor assembly to be cooled even more effectively.

In one aspect, the method has the following further method step:
arranging an electrically insulating additional substrate, which has a metallization layer on each of its top and bottom sides, on the second side of the first heat sink opposite the first side, and establishing a thermal and electric connection between the second side of the first heat sink and the bottom-side metallization layer of the additional substrate facing the first heat sink.

In one aspect, the power electronics component has an electrically insulating first substrate, which has a metallization layer on each of its top and bottom sides, and a semiconductor assembly mounted on the first substrate, which semiconductor assembly has at least one first connection which is thermally and electrically connected to at least one region of the top-side metallization layer of the first substrate facing the semiconductor assembly. In addition, the power electronics component comprises an electrically insulating second substrate which is mounted on the semiconductor assembly and has a metallization layer on each of its top and bottom sides, wherein the semiconductor assembly has at least one second connection which is thermally and electrically connected to at least one region of the metallization layer of the second substrate facing the semiconductor assembly, a first heat sink which is thermally and electrically connected to the bottom-side metallization layer of the first substrate facing away from the semiconductor assembly, wherein the first heat sink has at least one first cooling channel through which coolant can flow, and a second heat sink which is thermally, and in particular also electrically, connected to the metallization layer of the second substrate facing away from the semiconductor assembly, wherein the second heat sink has at least one second cooling channel through which coolant can flow.

In one aspect, the power electronics component has a semiconductor assembly that can be cooled on both its top side and its bottom side. For this purpose, the bottom side of the semiconductor assembly is thermally and electrically connected to the metallization of the first substrate facing the semiconductor assembly, wherein the metallization of the first substrate facing away from the semiconductor assembly is thermally, and in particular also electrically, connected to the first heat sink. This arrangement allows for improved heat dissipation on the bottom side of the semiconductor assembly. The top side of the semiconductor assembly is correspondingly thermally and electrically connected to the metallization of the second substrate facing the semiconductor assembly, wherein the metallization of the second substrate facing away from the semiconductor assembly is thermally, and in particular also electrically, connected to a second heat sink. This also allows for efficient heat dissipation on the top side of the semiconductor assembly. The heat dissipation is further improved in that both the first heat sink and the second heat sink each have at least one cooling channel through which coolant can flow. Thanks to the power electronics component described here, even large amounts of heat generated by the semiconductor assembly can be efficiently dissipated. It is particularly advantageous that the heat sinks are thermally coupled via the metallization of the first and second substrates, because coupling the heat sinks via metallization layers improves heat transfer. The solution described here provides for a compact and mechanically stable component that cools the semiconductor assembly on both sides and allows for improved heat dissipation.

In a further aspect, a method for joining a power electronics component is disclosed. The method comprises arranging a semiconductor assembly on an electrically insulating first substrate, which has a metallization layer on each of its top and bottom sides, and establishing at least one thermal and electric connection between at least one first connection of the semiconductor assembly and at least one region of the top-side metallization layer of the first substrate facing the semiconductor assembly. In addition, the method comprises arranging an electrically insulating second substrate, which has a metallization layer on each of its top and bottom sides, on the semiconductor assembly and establishing at least one thermal and electric connection between at least one second connection of the semiconductor assembly and at least one region of the top-side metallization layer of the second substrate facing the semiconductor assembly. In addition, the method comprises arranging a first heat sink on the first substrate, wherein the first heat sink has at least one first cooling channel through which coolant can flow, establishing a thermal and electric connection between the first heat sink and the metallization layer of the first substrate facing away from the semiconductor assembly, arranging a second heat sink on the second substrate, wherein the second heat sink has at least one second cooling channel through which coolant can flow, and establishing a thermal and electric connection between the second heat sink and the metallization layer of the second substrate facing away from the semiconductor assembly.

In order to describe the layout of the power electronics component, terms such as “on”, “top side”, “bottom side” are used in this application to describe the geometric arrangement of the components of the power electronics component. These indications refer to a power electronics component placed on a horizontal surface. The use of these terms should not be understood to be restrictive in relation to the spatial orientation of the power electronics component. Rather, the power electronics component can be used in any spatial orientation. In particular, the power electronics component can be used in any installation position.

In one aspect, the semiconductor assembly comprises one or more semiconductor components, in particular power semiconductor components, such as those designed for currents ≥10 A and/or designed for voltages ≥400 V.

In one aspect, the semiconductor assembly is preferably arranged in a “bare die layer”. The term “bare die layer” refers here to a layer in which one or more semiconductor components are arranged as “bare dies”. The term “bare dies” comes from the English language. The following terms are also often used synonymously: “Bare chips”, “die” or “chip”. These terms refer to integrated electronic components that are not conventionally installed in a plastic or ceramic housing, but are processed without a housing. They are applied directly to the conductor structure of the substrate and can be electrically connected to surrounding components or conductor structures by means of bonding, in particular chip bonding. The term “bonding” refers here to the connection of bare dies with other components or conductor structures.

The bare die layer can have regions in which no semiconductor components are arranged. These regions can be filled with a filling material. This filling material can be designed to improve stability, to reduce mechanical stresses and/or to improve electric insulation, such as by extending air and/or creepage distances.

The term “connection” refers here to any type of connection or terminal that the semiconductor assembly may have, for example: a collector connection, an emitter connection, a drain connection, a source connection, a control connection or a test connection. In particular, it may be a power terminal, for example: a collector connection, emitter connection, drain connection, source connection. Each connection can have a connection surface using which contact to one of the metallizations can be established. In particular, a power terminal may have a relatively large area of 2 mm² or more.

The term “electric connection” refers here in particular to a high-quality, low-resistance and low-inductance connection. It should preferably have a contact resistance of 0.2Ω or less and preferably a contact inductance of 5 nH or less.

The term “thermal connection” refers here in particular to a high-quality thermal connection with low thermal resistance.

In one aspect, a requirement results from predictable power dissipation, such as in a semiconductor component, such as a transistor, a diode, in particular a PIN diode, for example for switching RF power between different paths, or from or a combination of a transistor with a diode, and a system thermal resistance from bare die to the coolant. The system thermal resistance is calculated as the sum of all thermal resistances. The first important thermal resistance that cannot be influenced by the cooling arrangement is the thermal resistance between the bare die or chip and the bare die cooling surface. It is specified by the manufacturer as RthJ/C (junction/case). It is dependent on the cooling surface of the semiconductor component and can be between 0.7 K/W and 0.8 K/W for currently common transistors, for example.

As previously mentioned, modern plasma process applications, particularly in the production of semiconductors such as computers or memory chips, place high demands on electric power converters. These can often only be achieved if the semiconductor components are designed to absorb a considerable amount of power loss. This can be greater than or equal to 1 kW, for example. In order to achieve this, a thermal resistance of less than or equal to 0.15 K/W measured from the bare die or chip to the coolant should preferably be attained. After extensive simulations and tests, it was ascertained that this can be attained with the present power electronics component. In this context, further improvements are not excluded and are always considered desirable.

In one aspect, the first heat sink is implemented at least partially in the form of a layered structure of thermally connected metal foils, preferably copper foils. Such a production of a monolithic heat sink is disclosed, for example, in DE4315580A1, in which individual metal foils are at least partially structured by means of laser processing and/or punching and/or produced by means of electroplating processes and then joined together. Such a method is subsequently referred to as a “metal layer bonding method”. Preferably, the first heat sink is produced at least partially by means of a metal layer bonding method. Preferably, the metal foils are bonded together using a bonding method under high pressure and at high temperature.

In one aspect, the first heat sink is made of copper. Copper exhibits very good thermal conductivity and electrically conductive properties. For example, oxide layers can be formed on the surfaces of copper layers, which are then welded together, wherein the temperature is preferably selected so high that the oxide layers melt but the metal foils do not. In this way, the metal foils combine to form a monolithic heat sink. If the metal foils are made of copper, for example, this is also referred to as direct copper bonding, or DCB for short.

In one aspect, the metal foils have a thickness of 0.4 mm or less, in particular 0.25 mm or less. This allows for very effective heat dissipation.

In one aspect, the first heat sink has at least one first cooling channel through which coolant can flow, wherein the at least one first cooling channel is implemented in the form of at least one recess provided in the metal foils. For example, the metal foils can be structured or produced in such a way that closed channels are created after the layers are joined together, through which a cooling medium can flow.

In an aspect, it is advantageous if the first heat sink is connected to the bottom-side metallization layer of the first substrate facing away from the semiconductor assembly by means at least one of the following methods or processes: sintering, pressing, a metal layer bonding method, in particular DCB, at least one soldered joint.

In one aspect, the first heat sink is produced at least partially by means of an additive manufacturing method, preferably by means of selective laser melting. Such an additive manufacturing method is disclosed, for example, in EP1672690B1 referring to a “Micro heat sink”. The now more common term “additive manufacturing method” is described there on the basis of the method of selective laser melting. However, “additive manufacturing methods” can also include methods other than selective laser melting. An additive manufacturing method is characterized by the fact that the structure is gradually applied from the same material. Here, the material can be melted during application. Lasers are currently the best option for achieving particularly fine structures.

In one aspect, a plurality of cooling pins are arranged in the first cooling channel or in a partial region of the first cooling channel and extend into the first cooling channel. The coolant flowing in the cooling channel flows around the cooling pins. This allows for an improved thermal coupling to be achieved.

In one aspect, it is advantageous if the first heat sink comprises a coolant feed and a coolant discharge, both of which are fluidically connected to the first cooling channel, wherein the first heat sink is designed in such a manner that the first heat sink can be mounted in a detachable manner on a cooling unit comprising a first fluid port and a second fluid port and that, when the first heat sink is mounted on the cooling unit, a first fluidic connection can be established between the coolant feed of the first heat sink and the first fluid port of the cooling unit and a second fluidic connection can be established between the coolant discharge of the first heat sink and the second fluid port of the cooling unit. The cooling unit is designed to supply coolant to the first heat sink and to discharge the coolant again. For example, the first heat sink can be designed in such a way that fluid-tight fluidic connections can be formed between the first heat sink and the cooling unit when the first heat sink is mounted in the cooling unit. In this context, it is possible, for example, to remove the power electronics component from the cooling unit as required. This enables, for example, a detachable mounting of the power electronics component in the cooling unit. This is particularly advantageous in terms of maintenance and repair.

In one aspect, the first heat sink is a micro heat sink and the semiconductor assembly is an electronic component. A micro heat sink is designed to cool a single electronic component. This allows for individual cooling that can be adjusted to the heat generated by the electronic component.

In one aspect, the first substrate is connected to the first heat sink at a first cooling wall in a materially bonded manner, wherein the power electronics component is designed such that, during operation, the coolant is guided through the first cooling channel at a predetermined operating pressure, wherein a distance between the first cooling channel and the first cooling wall is selected to be so small that the first heat sink cannot ensure sufficient form stability and/or tightness at the predetermined operating pressure without the first substrate connected to it in a materially bonded manner, and the first substrate and its materially bonded connection to the first heat sink on the first cooling wall are designed such that the power electronics component can ensure this sufficient form stability and tightness. A typical predetermined operating pressure can be, for example, 3 bar or more overpressure relative to ambient pressure. There are several ways to design the substrate and its materially bonded connection with the heat sink on the cooling wall in such a way that the cooling arrangement can ensure sufficient form stability and tightness. For example, the substrate can have a certain continuous minimum thickness. For example, the substrate can be made thicker at the points where the distance between the cooling channel and the substrate is particularly thin in order to ensure stability only here. However, the form stability of the substrate is only one parameter. Also important is the strength of the materially bonded connection between the substrate and the heat sink. The more stable this can be designed, the thinner the substrate can be.

In one aspect, it is advantageous if the first cooling channel is characterized in that its cross-section has, at least in sections, a geometric shape whose width, measured parallel to the first cooling wall, decreases in the direction of the first cooling wall, and wherein the geometric shape of the cross-section at the first cooling wall has a distance from the substrate which is designed such that, at the predetermined operating pressure of the coolant, the first heat sink cannot ensure sufficient form stability and/or tightness without the first substrate connected to it in a materially bonded manner.

In one aspect, it is advantageous if at least one control connection and at least one first power terminal are arranged on a first side of the semiconductor assembly and at least one second power terminal is arranged on the second side of the semiconductor assembly. In this aspect, the first power terminal can be electrically contacted from the first side and the second power terminal from the second side. This allows for electric contacting of the power terminals over a large area. Given the high currents that flow through the power terminals, this is an advantage. In the following, some solutions are discussed as to how the control connection, which generally conducts less current compared to the power terminals, can be guided out of the power electronics component.

In one aspect, the metallization layer facing the first side of the semiconductor assembly has at least one first metallization region for making electric contact with at least one control connection of the semiconductor assembly and at least one second metallization region for making electric contact with at least one first power terminal of the semiconductor assembly, wherein the at least one first metallization region and the at least one second metallization region are electrically isolated from one another, and wherein at least one first metallization region is guided to the side of the component and can be electrically contacted from the side of the component. In this aspect, at least one control connection can be electrically contacted by at least one first metallization region and at least one first power terminal can be electrically contacted by at least one second metallization region. This allows the control connection to be guided to the side of the component.

In one aspect, it is advantageous if the at least one first metallization region and the at least one second metallization region of the metallization layer are separated from one another by means of an etching process. The etching process can be used to divide the metallization layer into different, electrically isolated metallization regions.

In one aspect, a contacting structure is provided for making electric contact with the control connection, which contacting structure is arranged on the metallization facing the first side of the semiconductor assembly, wherein the contacting structure comprises at least one insulating material layer and one conductive layer, and wherein the conductive layer is electrically connected to the control connection and guided to the side of the component. In this regard, it is particularly advantageous if the conductive layer, which is used to guide out the control connection, is separated electrically from other metallization regions by means of insulating material layers.

In one aspect, electric contact of at least one control connection of the semiconductor component is made via at least one through-connection extending through the first heat sink, also referred to as a: via. Via the at least one via, at least one of the control connections can be contacted from the side facing away from the semiconductor assembly.

In one aspect, a via insulation can be provided for a via in the region of one or both heat sinks to protect the through-connection from electric contact with the heat sink.

In one aspect, the second heat sink is produced at least partially using a metal layer bonding method, in particular DCB method. It is advantageous in this regard if the metallization layers of the second substrate and the metal foils of the second heat sink are joined in one process. This means that all the metal foils that form the heat sink and the metallization layer of the substrate are bonded together in one process.

In one aspect, the first heat sink is produced at least partially using a metal layer bonding method, in particular DCB method. It is advantageous if the bottom-side metallization layer(s) of the first substrate and the metal foils of the first heat sink are joined in one process. This means that all the metal foils that form the heat sink and these metallization layer(s) of the substrate are bonded together in one process.

In one aspect, the second heat sink is implemented at least partially in the form of a layered structure of thermally connected metal foils, preferably copper foils. For example, metal foils can be at least partially structured by means of laser processing and/or punching and/or produced by means of electroplating processes and then joined together. Preferably, the second heat sink is produced at least partially by means of a metal layer bonding method. Preferably, the metal foils are bonded together using a bonding method under high pressure and at high temperature.

In one aspect, the second heat sink is made of copper. Copper exhibits very good thermal conductivity and electrically conductive properties. For example, oxide layers can be formed on the surfaces of copper layers, which are then welded together, wherein the temperature is preferably selected so high that the oxide layers melt but the metal foils do not. In this way, the metal foils combine to form a monolithic heat sink. If the metal foils are made of copper, for example, this is also referred to as direct copper bonding, or DCB for short.

In one aspect, the metal foils have a thickness of 0.4 mm or less, in particular 0.25 mm or less. This allows for very effective heat dissipation.

In one aspect, the second heat sink is connected to the metallization layer of the second substrate facing away from the semiconductor assembly by means at least one of the following methods or processes: sintering, pressing, a metal layer bonding method, in particular DCB, at least one soldered joint.

In one aspect, the first substrate and/or the second substrate is one of the following: a ceramic substrate, a direct-bonded copper (DBC) substrate, an insulated metal brazed (IMB) substrate, an active metal brazed (AMB) substrate, a thick-film substrate.

In one aspect, the first substrate is arranged substantially parallel to the second substrate. The semiconductor assembly is surrounded at the bottom by the first substrate and at the top by the second substrate, each of which is thermally connected to the associated heat sinks. This allows for efficient heat dissipation to both sides. The symmetrical arrangement of the substrates results in a space-saving layout and a favorable geometry with regard to the installation of the component.

In one aspect, the first heat sink and the second heat sink are each micro heat sinks and the semiconductor assembly is an electronic component. In this aspect, the first and second heat sinks are each designed as micro heat sinks. A micro heat sink is designed to cool a single electronic component. In the present case, the electronic component is therefore cooled by both the first and the second heat sink, both of which are designed as micro heat sinks. The electronic component together with the two micro heat sinks can, for example, be removed from a larger component and reinserted into it, which is advantageous in terms of maintenance and repair. This allows for individual cooling that can be adjusted to the heat generated by the electronic component.

In one aspect, it is advantageous if the component comprises control electronics which are arranged on the side of the additional substrate facing away from the first heat sink, wherein at least one connection of the control electronics is thermally and electrically connected to at least one region of the metallization layer facing the control electronics. Preferably, the control electronics, which generate the signals required for controlling the semiconductor assembly, can be accommodated on the additional substrate. In this way, it is possible to generate the control signals for the semiconductor assembly located on the first substrate in the immediate spatial vicinity of the semiconductor assembly. This can reduce or avoid signal interference of the control signals, which can be caused by the coupling of electromagnetic interference signals, for example. Via the at least one via, for example, the control signals generated by the control electronics can be routed directly to the semiconductor assembly in order to control power electronics components there, for example. In this context, a via insulation can be provided in the region of the heat sink to protect the through-connection from electric contact with the heat sink.

In one aspect, at least one connection of the control electronics is electrically connected to a connection of the semiconductor assembly via at least one via, which extends through the first heat sink.

In one aspect, the first heat sink has at least one first cooling channel through which coolant can flow. It is advantageous in this regard if the first heat sink is implemented in the form of a layered structure of thermally connected metal foils, preferably copper foils, and the first cooling channel is implemented in the form of at least one recess provided in the metal foils.

In one aspect, the first substrate and/or the additional substrate is one of the following: a ceramic substrate, a direct-bonded copper (DBC) substrate, an insulated metal brazed (IMB) substrate, an active metal brazed (AMB) substrate, a thick-film substrate.

In one aspect, further preferably, the first substrate is arranged substantially parallel to the additional substrate. The arrangement of the first substrate on the bottom side of the first heat sink and the second additional substrate parallel to it on the top side of the heat sink creates a compact geometric structure in which the heat sink is stabilized by the two substrates. In this regard, the coolant feed and coolant discharge of the heat sink can, for example, be accessible from the side of the heat sink or, alternatively, can be guided through the additional substrate, for example.

Aspects of the present disclosure also provide an electric power converter for an industrial process assembly, preferably a plasma process assembly or heating assembly, having a power electronics component as described above or below. In particular, the electric power converter can be designed here to generate an RF output power. The term “RF output power” here refers to an output power that is in the range of 1 kW or more, in particular 10 kW or more, preferably 100 kW or more at frequencies ≥20 kHz, preferably ≥200 kHz, in particular ≥2 MHz.

As mentioned at the outset, such a power converter is particularly dependent on very powerful and reliable cooling, which can be achieved particularly well with such a power electronics component.

EP3317966B1 describes an arrangement with a printed circuit board for cooling on a metallic cooling plate. Here, the circuit board has a bottom layer, wherein the bottom layer is designed as a metallic layer that serves as a reference ground. However, the heat transfer from the circuit board to the cooling plate is not optimal. The circuit board often does not lie flat on the cooling plate. In order to counteract the lack of heat transfer due to this disadvantage, heat-conducting paste is used, but this is disadvantageous in the manufacturing process and can age, which can further deteriorate the heat transfer.

In one aspect, the power electronics component, in this regard, comprises two power semiconductor components, in particular transistors, which each have a first and a second power terminal and a control connection, wherein both power semiconductor components, in particular transistors, are connected to one of their power terminals in order to form a series circuit, wherein a direct current or direct voltage is connected to the remaining power terminals. This can be done directly, for example, or via a filter or an inductance. Furthermore, control electronics can be provided which are connected to the control connections of the power semiconductor components, and the control electronics are designed to control the power semiconductor components, in particular the transistors, in such a manner that they can generate an RF power and transfer from a first conductive state to a second conductive state, wherein the conductivity of the two states is different. Such an arrangement can be operated very efficiently, such as in Class D, Class E or Class F or Class F-1 operation. Such an operation creates less power loss than Class A or Class B operation, for example. In combination with the very good cooling by means of the described power electronics component, an even further improved supply of the industrial processes can be achieved, for example by allowing them to be supplied with higher power. Typical operating classes for generating RF power are described, for example, in EP 1 601 098 B1.

In one aspect, the two power semiconductor components, in particular transistors, can each be connected with their first power terminal to a common connection point, in particular ground connection point, wherein the power semiconductor components, in particular transistors, are in particular identically designed and are arranged on the multilayer printed circuit board. In this way, cooling can be further improved and the power yield further increased.

In one aspect, one of the two power semiconductor components, in particular transistors, can be connected with its first power terminal to the other power semiconductor component, in particular transistor, and with the second power terminal to a common connection point, wherein the power semiconductor components, in particular transistors, are in particular identically designed and are arranged on the multilayer printed circuit board. In this way, cooling can be further improved and the power yield further increased.

In one aspect, a power transformer having a primary winding and a secondary winding can be arranged on the printed circuit board, wherein the primary winding is connected to the at least one power terminal of the power semiconductor components, in particular transistors. The primary winding and the secondary winding of the power transformer can each be designed as planar conductor tracks, which are arranged in different layers of the printed circuit board. In this context, the printed circuit board can have a thermal connection with the cooling unit. In this way, cooling can be further improved and the power yield further increased.

In one aspect, the thermal connection to the cooling unit can have a thermally conductive compensation layer having a first face fixedly connected to the first face of the printed circuit board. Furthermore, the thermal connection can alternatively or in addition have a connection layer which is fixedly connected with its first face to the second face of the thermally conductive compensation layer and is fixedly connected with its second face to the cooling unit.

In one aspect, the cooling unit can have a heat distributing characteristic here. It can be either designed as electrically conductive or insulating here.

The wording “fixedly connected” means here that the connection is firm and durable, such as bonding, welding, soldering or pressing, and preferably only separable with high heat and/or mechanical pressure.

In one aspect, the connection can be established as a material bond. This prevents air entrapment and ensures good thermal conduction properties.

In one aspect, the bottom-side metallization layer can form a monolithic unit with the heat sink. This can be achieved using a direct-bonded copper (DBC) method, for example. Alternatively or in addition, this can be achieved using an additive manufacturing method on the bottom-side metallization layer. With both methods, the bottom-side metallization layer can be included in the method step.

In one aspect, the thermally conductive compensation layer is suitable for conducting heat from the printed circuit board towards the cooling unit. It can compensate for unevenness caused, for example, by conductor tracks, windings or contact pads on the bottom side of the printed circuit board and provide a homogeneous and flat plane in the direction of the cooling unit.

In one aspect, the thermally conductive compensation layer can consist of a prepreg or unreinforced adhesive. The insulating printed circuit board and the heat distributor can be connected by heating and pressing together a prepreg inserted therebetween. “Prepreg” is a common material name, which is an abbreviation of “pre-impregnated”. This usually refers to pre-impregnated, mostly planar, flat textile semi-finished products with a thermoplastic or thermosetting matrix, such as unidirectional layers of threads, fabrics or scrims with threads often arranged at right angles.

In one aspect, prepegs are cured under temperature and pressure to produce components. For example, they are prefabricated in web form, wound on rolls. The term “prepreg” includes not only unidirectionally reinforced or flat semi-finished products, but also other preforms of basically any shape, which in the broadest sense consist of a fiber-filled, uncured thermosetting matrix. In this context, the matrix is in a partially cross-linked state and is pasty to solid, but can be liquefied again by heating.

Prepregs are machine-processable and are therefore often used in automated processes. They produce consistent and high quality. Advantages are the low undulation and high fiber volume content thereof. Curing at high temperatures enables short cycle times in further processing. Processing requires high investment costs, e.g., for autoclaves, laying robots and refrigerated storage. Such prepregs are generally used to join a plurality of printed circuit boards together to form a multilayer printed circuit board. In order to ensure a secure and long-lasting joint, the materials to be joined should have very similar properties regarding the expansion thereof when heated. However, this is not necessarily the case with the printed circuit board and the heat distributor, in particular if the heat distributor is made of ceramic. This is an argument initially against such a connection. However, ceramics exhibit very good thermal conductivity and at the same time very good electric insulating properties and also low dielectric losses when insulating high-frequency signals of high voltage. Contrary to expectations, tests have shown that even with small dimensions, a secure and long-lasting joining of materials is possible with different properties, such as ceramic with FR-4 and/or ceramic with PTFE material. The wording “small dimensions” means here a composite area of less than 400 cm² and/or with a maximum length of 20 cm.

In one aspect, the connection layer can comprise an adhesive on the basis of a resin. It can be thinner than the thermally conductive compensation layer.

In one aspect, the connection layer can comprise an adhesive film.

Together, the two layers can form a solid connection with good thermal conduction properties to the cooling unit.

In one aspect, such an electric power converter will improve the properties of a power supply system that has LDMOS transistors as the elements to be cooled, as disclosed, for example, in DE 10 2013 226 537 A1, EP 3 317 964 B1 and EP3 317 965 B1. The load capacity of LDMOS transistors in such power supply systems often reaches its limits because they get too hot, even though neither their maximum voltage rating nor their maximum current rating is reached. This means that with an improvement in cooling as described above and below, such power supply systems can be operated much more reliably.

In one aspect, such an electric power converter will improve the properties of a power supply system that provides very high voltages at its output, in particular voltages greater than or equal to 1 kV, particularly preferably greater than or equal to 2 kV, and in particular greater than or equal to 4 kV. It is particularly preferred when they are also provided in a pulsed manner, as described for example in EP 4 235 737 A1 as a high-power generator. Since the switching elements described there must switch on even when a voltage is applied to their power terminals, these switching operations are particularly high in losses. EP 4 235 737 A1 describes a very complex cooling process, which can be improved with the device and/or method described here.

In one aspect, such an electric power converter will improve the characteristics of a power supply system having a coupler unit, in particular a phase-shifting coupler unit, preferably a 90° hybrid coupler, as also described, for example, in DE 10 2013 226 537 A1 or WO 2020/025547 A1. In this regard, the coupler unit described there can be used independently of other features such as those described in DE 10 2013 226 537 A1 or WO 2020/025547 A1. The coupler unit can preferably have a first and a second planar inductance, as also described in DE 10 2013 226 537 A1.

In one aspect, such an electric power converter will improve the properties of a power supply system having GaN transistors as the elements to be cooled. Such power converters are described, for example, in WO 2010/091696 A1 or WO 2010/091697 A1.

In one aspect, such an electric power converter will improve the characteristics of a power supply system having SiC transistors as the elements to be cooled. Such power converters are described, for example, in WO 2020/025547 A1.

The patent publications DE 10 2013 226 537 A1, EP 3 317 964 B1, EP3 317 965 B1, WO 2010/091696 A1, WO 2010/091697 A1, WO 2020/025547 A1 and EP 4 235 737 A1 are included in their entirety by reference in this application.

Further advantageous configurations are described in more detail below with reference to a number of exemplary embodiments shown in the drawings, to which the development described herein is not limited, however.

In the following description of embodiments, identical reference signs designate identical or comparable components.

The semiconductor assembly 28 described in the following figures comprises electronic components and assemblies for power applications, in particular power semiconductor components, such as transistors or diodes, in particular PIN diodes, such as for switching RF power between different paths, or a combination of a transistor with a diode designed for currents ≥10 A and voltages ≥400 V, for example. These components can generate significant waste heat during operation, which must be dissipated during operation. The load capacity of such electronic components and assemblies often reaches its limits because they get too hot, even though neither their maximum voltage rating nor their maximum current rating is reached.

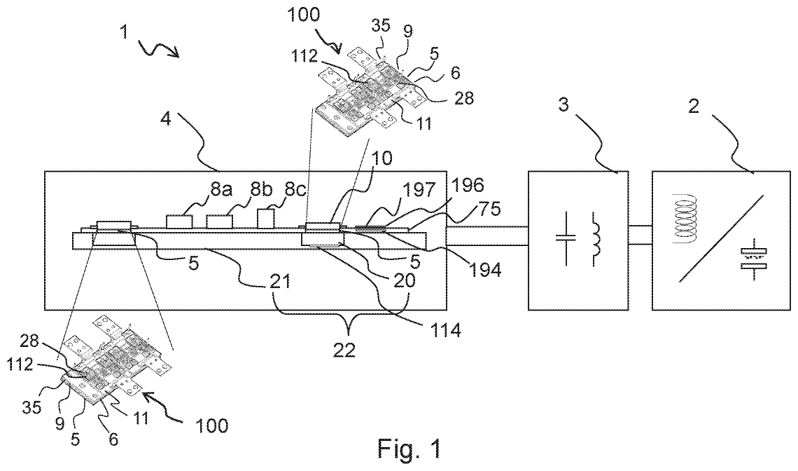

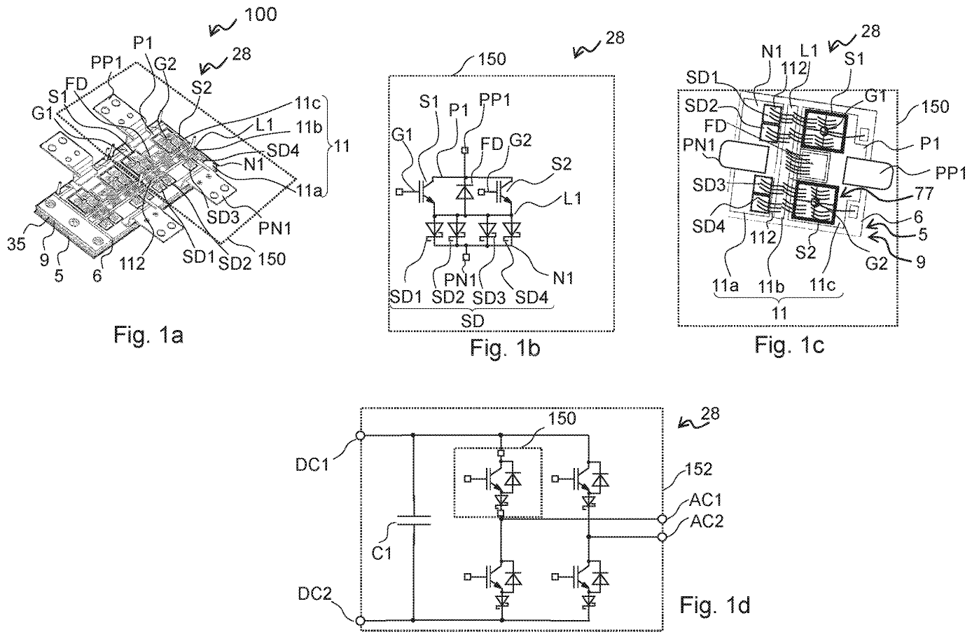

FIG. 1 shows an industrial process assembly 1 with an electric power converter 4 in an industrial process assembly, preferably a plasma process assembly or a heating assembly, with a first embodiment of a power electronics component 100.

The industrial process assembly 1 has: an electric power converter 4, a load 2, preferably a plasma process or heating process, e.g., an induction or microwave heating process, wherein the load 2 is electrically connected to the electric power converter 4, such that the electric power converter 4 can supply the load 2 with the required electric power, optionally an additional adaptation unit 3 which is connected between the power converter 4 and the load 2.

The power converter 4 has: two of the first power electronics components 100, as previously or subsequently described, for example, in the description of FIGS. 1a, b, c, a cooling unit 22, which, as described above and below, has one or more distribution units 20 and a carrier unit 21, a printed circuit board 75, a unit 10 to be cooled, in particular an electric unit, preferably a semiconductor assembly, preferably having a power semiconductor component, further electronic components 8a, 8b, 8c, wherein the further electronic components 8a, 8b, 8c and the unit 10 to be cooled are arranged on or at a printed circuit board 75 and are connected to electric contacts, wherein the unit 10 to be cooled is fixedly connected, in particular by means of material bonding, to the heat sink 5.

Two power semiconductor components, in particular transistors S1, S2, which each have a first and a second power terminal and a control connection G1, G2, 128, wherein both transistors S1, S2 can be connected to one of their power terminals in order to form a series circuit, are arranged here on or at the printed circuit board 75 as the unit 10 to be cooled. A direct current or direct voltage DC+, DC− can be connected to the remaining power terminals. Control electronics 114 can be connected to the control connections of the power semiconductor components.

A power transformer 197 having a primary winding 196 and a secondary winding 194 is also arranged on the printed circuit board 75 here. The primary winding 196 and the secondary winding 194 of the power transformer 197 are each designed here as planar conductor tracks, which are arranged in different layers of the printed circuit board 75. The printed circuit board has a thermal connection with the cooling unit 22.

Here, the thermal connection with the cooling unit 22 can have a thermally conductive compensation layer which is fixedly connected with its first face to the first face of the printed circuit board 75 and a connection layer which is fixedly connected with its first face to the second face of the thermally conductive compensation layer and fixedly connected with its second face to the heat distributor.

FIGS. 1a to 1d are described in context.

FIG. 1a shows a detailed embodiment of a power electronics component 100 for an industrial process assembly 1, preferably a plasma process assembly or a heating assembly, as already shown in FIG. 1.

FIG. 1b shows a circuit diagram of an embodiment of a semiconductor assembly 28 designed as a semiconductor switching unit 150. In FIG. 1a, two such semiconductor switching units 150 are arranged next to one another on a heat sink 50. For example, a half bridge can be provided for a Class D amplifier or a medium frequency (MF) power converter. These are preferably used for induction heating processes and/or plasma treatment processes.

Two such half bridges can be used to provide a full bridge, such as the one shown in FIG. 1d. For this purpose, the semiconductor assembly 28 with the top-side metallization 11 and the first substrate 6, which is arranged on the top side of the heat sink in FIG. 1a, can be arranged again as structurally identical on the bottom side.

FIG. 1c shows a detailed view of a power electronics component from FIG. 1a.

FIG. 1d shows a circuit diagram of an embodiment of a semiconductor assembly designed as an AC converter assembly, here in particular as a full bridge.

Three half bridges, as shown in FIG. 1a, can be used to provide a 3-phase AC converter, such as for feeding power into a supply network, for example at 50 or 60 Hz, or a drive circuit for an electric motor.

The power electronics component 100 has: an electrically insulating first substrate 6, which has a top-side metallization layer 11 on its top side and a bottom-side metallization layer 9 on its bottom side, wherein the top-side metallization layer 11 is divided into at least three electrically isolated regions of a conductor structure 11a, 11b, 11c.

The power electronics component 100 further has: a semiconductor assembly 28 which is mounted on the first substrate 6 and which, in turn, has: at least two semiconductor components 110a, 110b, 110c connected in series, at least one of which is a controllable power semiconductor component, such as a transistor S1, S2 or a PIN diode, wherein the two semiconductor components 110a, 110b, 110c connected in series have the following: in each case at least one first connection 77, in particular designed as a collector connection surface 84 or source connection surface. Here, the first connection 77 is thermally and electrically connected to at least a first region of the conductor structure 11a, 11b, 11c, in each case at least one second connection 79, in particular designed as an emitter connection surface 78 or drain connection surface, which is electrically connected via a plurality of connecting lines 112 to a second connection surface 79 of another semiconductor component 110a, 110b, 110c and/or to one of the regions of the conductor structure 11a, 11b, 11c. In particular, the connecting lines 112 can be designed as bonding wires here.

The power electronics component 100 further has: a first heat sink 5 arranged on the first substrate 6, the first side of which facing the first substrate 6 is thermally connected to the bottom-side metallization layer 9 of the first substrate 6, which bottom-side metallization layer faces away from the semiconductor assembly 28, wherein the heat sink 5 is monolithically constructed and is fixedly connected to the bottom-side metallization layer 9 and has a first cooling channel 35 for guiding a cooling flow 36.

A heat sink made of metal can dissipate the heat very effectively. However, it can have the disadvantage of being electrically conductive. This is because there is a risk of currents being induced in it due to its electrically conductive properties. These could lead to additional unwanted losses. Here, however, it has been possible to reduce the dimensions of the heat sink to such an extent due to its particularly high heat dissipation efficiency that the induction of currents has also been significantly reduced.

The semiconductor components 110a, 110b, 110c are designed here as bare die semiconductor components and are thermally and electrically connected directly with their first connection 77 to one of the regions of the conductor structure 11a, 11b, 11c.

This allows the thermal resistance to be reduced even further. This allows the semiconductor assembly to be cooled even more effectively.

The three regions of the conductor structure 11a, 11b, 11c are shown here in FIG. 1a and FIG. 1c arranged next to one another in series.

This allows the inductance in the connecting lines to be reduced.

The two semiconductor components 110a, 110c connected in series are arranged here on two of the three regions of the conductor structure 11a, 11c.

This allows the inductance in the connecting lines to be reduced.

A third region of the conductor structure 11b is free of semiconductor components and, in particular, only has contacting connections 112, which are designed here as bonding wires.

This allows the inductance in the connecting lines to be reduced.

The third region of the conductor structure 11b is arranged here between the other two regions of the conductor structure 11a, 11c.

This allows the inductance in the connecting lines to be reduced.

Reducing the inductance in the connecting lines results in fewer unwanted and lossy oscillations in the semiconductor assembly. This additionally reduces heat generation. This means that the heat sink can also be made smaller in this way.

The component 100, 118, in particular the semiconductor assembly 28, can have: an AC converter assembly 152, having two DC voltage connections DC1, DC2 and two AC voltage connections AC1, AC2, which are designed to convert a DC voltage or a DC current into an AC voltage or into an AC current in the aforementioned power range and the aforementioned frequency range.

The AC converter assembly 152 can have a push-pull amplifier. This allows such a push-pull amplifier to be cooled particularly well.

The AC converter assembly 152 can have a bridge circuit, in particular a full bridge circuit, as shown as an example in FIG. 1d. This allows such a bridge circuit to be cooled particularly well.

The component 100, 118, in particular the semiconductor assembly 28, in particular the AC converter assembly 152, has here: a semiconductor switching unit 150, having two transistors S1, S2, wherein the transistors S1, S2 are electrically connected to one another at at least one power terminal.

This allows such a circuit to be cooled particularly well.

The component 100, 118, in particular the semiconductor assembly 28, preferably the AC converter assembly 152, has here: one, in particular two, or particularly preferably four identical semiconductor switching units 150, each having one or more control connections G1, G2, 128 and two power terminals, designed as a positive connection point P1 and a negative connection point N1.

This allows such a circuit to be cooled particularly well.

The component 100, 118, in particular the semiconductor assembly 28, preferably the AC converter assembly 152, has here: an intermediate circuit capacitor C1, which is arranged in particular very close to the semiconductor components, in particular power terminals of the transistors S1, S2, preferably with connecting leads having a length of less than or equal to 20 mm, particularly preferably less than or equal to 10 mm.

This allows the inductance in the connecting lines to be reduced.

The positive connection point P1 is designed here as one of the regions of the conductor structure 11c. This allows the inductance in the connecting lines to be reduced.

The negative connection point N1 is designed here as one of the regions of the conductor structure 11a. This allows the inductance in the connecting lines to be reduced.

A common connection point L1 is designed here as one of the regions of the conductor structure 11b. This allows the inductance in the connecting lines to be reduced.

The component 100, 118, in particular the semiconductor assembly 28, preferably the AC converter assembly 152, has here: A positive contact connection device PP1 and a negative contact connection device PN1, in each case designed for contacting a connection point on a printed circuit board 75 or a mechanical connecting line, such as a copper line. This allows the inductance in the connecting lines to be reduced.

The positive contact connection device PP1 is directly electrically connected to one of the regions of the conductor structure 11c, in particular to the positive connection point P1. In this regard, this connection is preferably produced by means of ultrasonic welding. This allows the inductance in the connecting lines to be reduced.

The negative contact connection device PN1 is directly electrically connected to one of the regions of the conductor structure 11a, in particular to the negative connection point N1. In this regard, this connection is preferably produced by means of ultrasonic welding. This allows the inductance in the connecting lines to be reduced.

Ultrasonic welding is a preferred technique for joining metals here: On the one hand in the form of wire bonding, on the other hand as ultrasonic welding for connecting connection devices on substrates, such as DCB substrates or strands and cables in external circuits. Here, ultrasonic welding uses power levels reaching from 500 W up to the kilowatt range. Piezoelectrically generated, low-frequency ultrasonic vibrations in the range of 15 to 50 kHz can be used for this purpose. These can differ in terms of the form of vibration and the force imprint. The following adverse effects or disadvantages are known to occur due to the application with these various types: Longitudinal vibrations tend to cause so-called hammering, which describes unwanted vibrations in a vertical direction and can have a negative effect on components or connections already located on the substrate. Torsional vibrations have a radius-dependent vibration amplitude, which can lead to insufficient connection build-up in the center.

In the present component, these disadvantages could be overcome and a reliable connection could be produced using ultrasonic welding, irrespective of the type of vibration, without negatively influencing other connections or components on the component in question.

Multiple transistors S1, S2 are electrically connected in parallel at their power terminals here. This allows the inductance in the connecting lines to be reduced.

At least one transistor S1, S2 is connected in series with a series diode arrangement SD, in particular having multiple series diodes SD1, SD2, SD3, SD4 connected in parallel.

In this regard, one, multiple or in particular all series diodes SD1, SD2, SD3, SD4 are designed as Schottky diodes.

A free-wheeling diode FD is connected electrically parallel with the power terminals of at least one of the transistors S1, S2.

FIG. 1a shows that a plurality of the semiconductor switching units 150 are arranged on a heat sink 50.

As a possible embodiment, one or more semiconductor switching units 150 can be arranged on a top side of the heat sink 5 and one or more further semiconductor switching units 150 can be arranged on a bottom side of the heat sink 50. For this purpose, a further substrate like the first substrate can be arranged on the other side of the heat sink 5. This is described in more detail below. In this manner, for example, a half bridge or full bridge can be cooled very effectively by a heat sink 50.

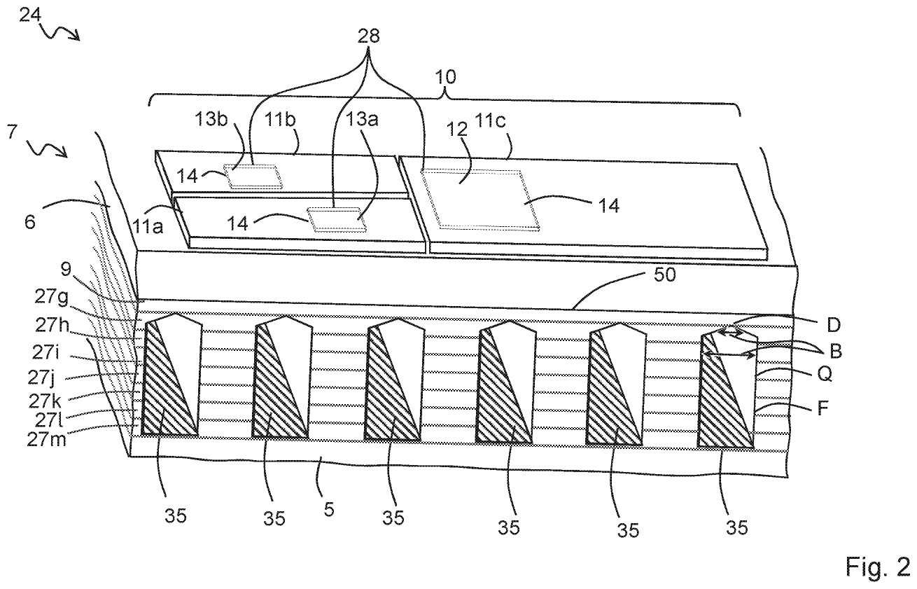

FIG. 2 shows an electronics assembly 24 with a cooling arrangement 7 and with an electric unit 10 to be cooled, which is preferably a semiconductor assembly. The electronics assembly 24 can be part of a power electronics component 188 as described above and below. Here, the cooling arrangement 7 has the first heat sink 5 and the first substrate 6 connected to it in a materially bonded manner. In this regard, the first heat sink 5 has a first cooling channel 35 through which coolant can flow in an intended flow direction. The first heat sink 5 here also has a cooling wall 50 on the side of the first cooling channel 35 facing the electric unit 10 to be cooled. The first substrate 6 is connected in a materially bonded manner to the first heat sink 5 at the cooling wall 50. On the side facing away from the first substrate 6 of the first heat sink 5, the electric unit 10 is connected to the first substrate 6 in a mechanically fixed manner. The electric unit 10 has: a conductor structure 11a, 11b 11c, together referred to as the metallization 11, a semiconductor assembly 28 having: a semiconductor component 12, which can be 3-pole component, in particular a transistor, or a PIN diode, such as for switching RF power between different paths, further 2-pole semiconductor components 13a, 13b to be cooled, such as diodes.

The 3-pole semiconductor component 12 can be designed as a bare die layer 14. In this manner, very direct heat coupling can be achieved. It can be connected in a materially bonded and fixed manner to the conductor structure 11c, for example by soldering. This results in a particularly low and stable heat transfer resistance.

One or more, in particular all of the 2-pole semiconductor components 13a, 13b to be cooled can be designed as a bare die layer 14. In this manner, very direct heat coupling can be achieved. It can be connected in a materially bonded and fixed manner to the conductor structure 11c, for example by soldering. This results in a particularly low and stable heat transfer resistance.

The 3-pole semiconductor component 12 and the 2-pole semiconductor components 13a, 13b are also referred to collectively as semiconductor components.

On the side of the first substrate 6 facing away from the bare die layer 14, a metallization is also mounted as a bottom side metallization 9.

The cooling arrangement 7 is designed such that, during operation, the coolant is guided through the first cooling channel 35 at a predetermined operating pressure, which is above the ambient pressure applied to the first substrate 6 on the side of the electric unit 10 to be cooled. A distance D between the first cooling channel 35 and the cooling wall 50 is selected to be so small that the first heat sink 5 cannot ensure sufficient form stability and/or tightness at the predetermined operating pressure without the first substrate 6 connected to it in a materially bonded manner. A typical predetermined operating pressure can be, for example, 3 bar, preferably 4 bar, or more overpressure relative to ambient pressure. However, the first substrate 6 and its materially bonded connection to the first heat sink 5 on the cooling wall 50 are designed such that the cooling arrangement 7 can ensure this sufficient form stability and tightness. The first heat sink 5 is monolithically constructed.

In particular, the distance D can be equal to or less than or equal to the thickness of the metallization 9 and/or less than or equal to 50 μm.

The first cooling channel 35 is characterized in that its cross-section Q has, at least in sections, a geometric shape F whose width B, measured parallel to the cooling wall 50, decreases in the direction of the cooling wall 50. In this case, the geometric shape F of the cross-section Q on the cooling wall 50 has a distance D from the first substrate 6, at least in sections, which is designed to be so small that, at the predetermined operating pressure of the coolant, the first heat sink 5 cannot ensure sufficient form stability and/or tightness without the first substrate 6 connected to it in a materially bonded manner.

As an alternative or at least partially in addition to the production of the heat sinks 5, 26 by means of a metal layer bonding method illustrated in FIGS. 2, 5, 6, 7, 8, 9, at least one of the heat sinks 5, 26 can be produced by means of an additive method, for example by means of selective laser melting. Additive manufacturing methods are characterized by the fact that the structure is gradually applied from the same material. Here, the material can be melted during application. For the production of such a heat sink, for example, the metallization applied to the side of the respective substrate facing away from the bare die layer 14 can be further structured using an additive manufacturing method.

Additive manufacturing methods enable components to be built up layer by layer directly from digital models by applying material in a targeted manner. In contrast to subtractive methods, in which material is removed, additive methods offer a high degree of flexibility in the design of complex geometries and are particularly efficient in terms of material consumption. In addition, additive manufacturing methods offer the possibility of producing monolithic components with cavities that have complex internal structures. These technologies are widely used in prototype development, small series production and increasingly also in industrial production.

A heat sink made of metal using an additive manufacturing method has a surface structure that is inherent to this manufacturing method. The structure is characterized by a rough surface, as the metal is first melted in the additive manufacturing method and then hardens through cooling. This roughness is therefore similar to a very fine crystal structure, such as occurs in nature. This roughness can lead to a particularly large surface area between the coolant and the metal. This increase in surface area can increase the heat transfer between the heat sink and the coolant. In addition, turbulence can be provided particularly well on the rough surface, which can also have a beneficial effect on the heat transfer between the heat sink and the coolant. The heat sink therefore has this rough surface structure inherent to the additive manufacturing method on the wall facing the coolant at least partially, preferably predominantly.

One or more outer sides of the heat sink can be ground or molded after the additive manufacturing process step. This can achieve an advantageous heat transfer from a winding or an electric conductor of the heat-generating component and/or from a core of the heat-generating component to the heat sink.

In one aspect, the heat sink is produced by selective laser melting (SLM). Selective laser melting is an additive manufacturing method used for the production of metal components. Here, the metal powder is applied layer by layer and precisely melted and solidified using a high-performance laser in order to create a three-dimensional component. A heat sink made of metal using SLM has a surface structure that is inherent to this manufacturing method. The structure is characterized by a particularly pronounced rough surface.

SLM is frequently used in industries that place high demands on component quality and precision, such as aerospace, medical technology, automotive engineering and tool manufacturing. Thanks to its ability to produce components with complex internal structures and high material utilization, the method is increasingly being used for demanding, customized applications.

The advantages of SLM methods include the production of complex geometries. The method allows for the production of highly complex and filigree structures that are difficult or impossible to implement with conventional manufacturing methods. Furthermore, the SLM method allows for the use of a wide variety of materials. SLM can be carried out with various metals such as aluminum, titanium, stainless steel and nickel, as well as numerous alloys with these materials, making it attractive to a plethora of industries. The SLM method is also very economical for small series production. SLM can be more economical than conventional manufacturing methods, in particular for the production of prototypes and in small series production, as no special tools or molds are required. The SLM method with copper had hardly been developed in the past and was considered particularly expensive.

The disadvantages of the SLM production method are the duration and the costs. For the same component size, a heat sink produced using an additive manufacturing method, in particular SLM, would be many times more expensive than a heat sink produced by means of machining, pressing or casting. In the past, this manufacturing method was therefore not recommended for larger series production and cost-critical developments. However, as it was possible to significantly reduce the size of the heat sink due to its significantly increased effectiveness, it was also possible to reduce costs and production time. This makes heat sinks produced using this additive manufacturing method, in particular SLM, interesting again. Since the weight and dimensions of the heat-generating component can also be significantly reduced in this way, such a heat sink becomes even more interesting. In the course of development, it was also possible to dissipate even more heat from a smaller face on the heat-generating component. This allowed the conductors and/or the core of the heat-generating component to be improved, in particular further reduced in size, which, in turn, allowed for the dimensions of a power converter to be further reduced in size. Components around the heat-generating component could also be arranged in a more space-saving manner. This also reduced the length of supply lines to these components. This has led to a reduction in electromagnetic interference and susceptibility to interference in the device and a further reduction in power loss. All these positive effects taken together justify the higher manufacturing costs of a heat sink produced using additive manufacturing methods, in particular SLM.

In one aspect, the heat sink comprises a single-piece main body. This means that the heat sink is designed as one continuous component. This can allow for increased mechanical stability and improved heat dissipation. By dispensing with a multi-part construction, potential weak points that could arise from connections or joints can be avoided. This can contribute to the longevity and reliability of the heat-generating component. This is particularly advantageous in connection with the liquid cooling of the heat sink, as the single-piece main body does not require any seals or the like, which would be necessary in multi-part constructions. This can reduce the risk of coolant emergence, which can further increase the operational safety and efficiency of the cooling system. This design can also simplify the production and assembly of the heat-generating component if fewer individual parts are required and the heat sink can be produced more efficiently as an integral part of the heat-generating component.

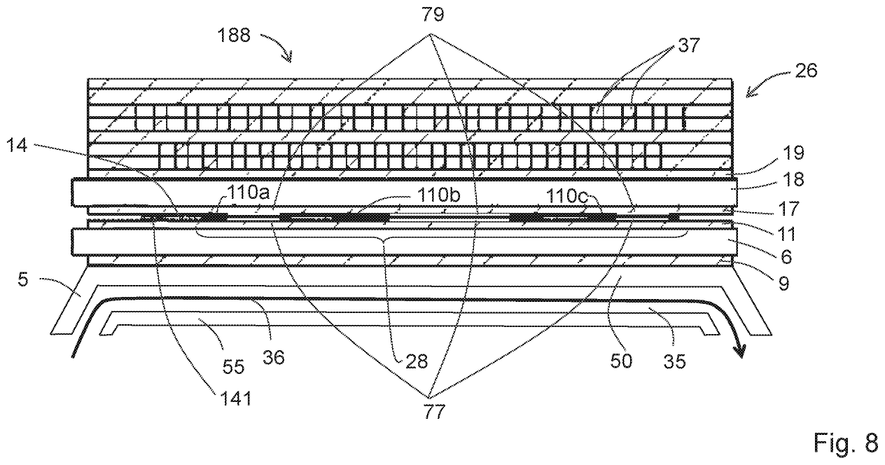

FIG. 8 shows an embodiment of the first power electronics component 188 in which double-sided cooling is provided for cooling the components, i.e., cooling from both the top and bottom sides of the components.

FIG. 8 shows a semiconductor assembly 28 in a bare die layer 14, which can comprise one or more semiconductor components 110a-c. These semiconductor components 110a-c can represent power semiconductor components, for example transistors S1, S2, and/or diodes SD1-SD4, FD for switching and conducting a very high power, a very high current and/or a very high voltage. The output can be 10 kW or more, for example. The voltage can be, for example, 400 V or more, in particular 1 kV or more. The current can be, for example, 10 A or more, in particular 50 A or more. The switching frequency can be, for example, 10 kHz or more, preferably 100 kHz or more, in particular 1 MHz or more. The semiconductor components are fixedly connected at their bottom side to the conductor structures 11a-c of the top side metallization 11, which is attached to the top side of a first substrate 6. The bare die semiconductor components and the top side metallization 11 can be joined together, for example, by means of at least one soldered joint, in particular a silver solder joint, and at least one welded joint, by means of sintering or a comparable method. This type of materially bonded connection exhibits very good and stable heat transfer properties.

The bare die layer 14 can have regions in which no semiconductor components are arranged. These regions can be filled with a filling material 141. This filling material 141 can be designed to improve stability, to reduce mechanical stresses and/or to improve electric insulation, such as by extending air and/or creepage distances.

The semiconductor components of the semiconductor assembly 28 mounted on the first substrate 6 have at least a first connection 77 which is thermally and electrically connected to at least one first region of the top-side metallization layer 11 of the first substrate 6 facing the semiconductor assembly 28.

An electrically insulating second substrate 18 is mounted on the semiconductor assembly 28 and has a metallization layer 17, 19 on each of its top and bottom sides.

The semiconductor components of the semiconductor assembly 28 have at least one second connection 79 which is thermally and electrically connected to at least one second region of the metallization layer 17 of the second substrate 18 facing the semiconductor assembly 28.

The first substrate 6 can preferably be a ceramic substrate. Ceramic materials that can be used include aluminum oxide ceramic, beryllium oxide ceramic, aluminum nitride ceramic and sapphire. The metallization 11 can be applied to the first substrate 6 by means of a previously mentioned bonding method, for example using direct-bonded copper. In this method, a copper foil can be bonded to the substrate, for example the ceramic substrate, under pressure and at high temperature. Alternatively, metallization methods such as IMB (insulated metal brazed) or AMB (active metal brazed) could be considered. This type of materially bonded connection exhibits very good and stable heat transfer properties.

A metallization 9 is also mounted on the side of the first substrate 6 facing away from the bare die layer 14. The metallization 9 can also be applied to the first substrate 6 by means of a bonding method, for example using direct-bonded copper. The first heat sink 5 is fixedly connected to the metallization 9. This type of materially bonded connection exhibits very good and stable heat transfer properties.

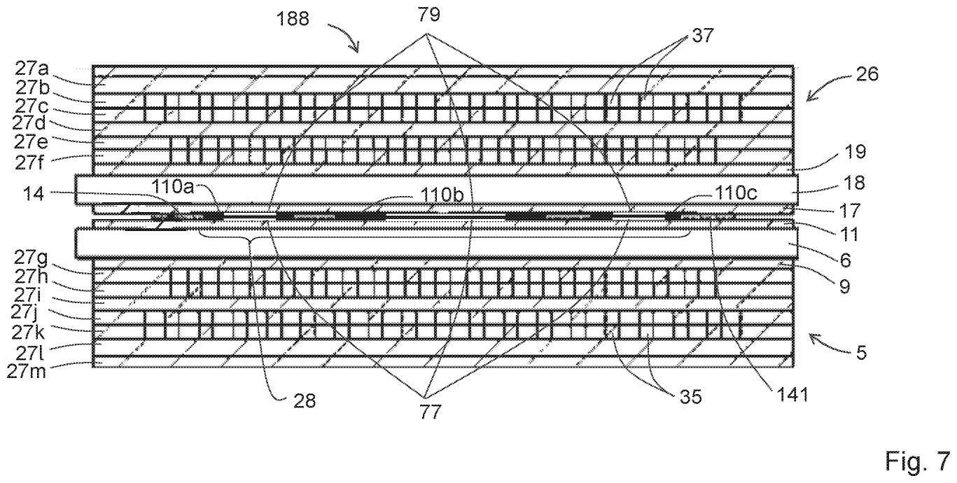

In the example shown in FIG. 7, the first heat sink 5 is produced using a metal layer bonding method. Here, individual metal foils 27a-m, preferably copper foils, are at least partially structured by means of laser processing and/or punching and/or produced by means of electroplating processes and then joined together. In this regard, the structuring or production is carried out in such a way that, after the layers have been joined together, closed first cooling channels 35 are created through which a cooling medium can flow. By means of a cooling channel structure, the coolant can be guided specifically to those regions of the first heat sink 5 that particularly require cooling. Preferably, the metal foils are bonded together using a bonding method under high pressure and at high temperature. For this purpose, oxide layers, for example, can be formed on the surfaces of the copper layers, which are then welded together, wherein the temperature is preferably selected so high that the oxide layers melt but the metal foils do not. In this way, the metal foils combine to form a monolithic heat sink. If the metal foils are made of copper, for example, this is also referred to as direct copper bonding, or DCB for short. The metal foils 27a-m preferably have a thickness of 0.4 mm or less, in particular 0.25 mm or less.

There are various options for the production of the structure shown in FIG. 7. According to a first possibility, the first substrate 6 provided with the metallizations 9 and 11 and the first heat sink 5 are each produced in separate steps. The first heat sink 5 is then fixedly connected to the metallization 9, for example by means of a bonding method, in particular using direct copper bonding. In this way, the metallization 9 can be part of the heat sink 5, in particular the monolithic heat sink. Other, less preferred, methods of joining the heat sink 5 to the metallization can be, for example: soldering, welding or sintering. According to a second, alternative manufacturing method, all layers, i.e., both the first substrate 6, the metal foil 9 and the metal foils 27g-27m, from which the first heat sink 5 is formed, are bonded together in a bonding method under high pressure and at high temperature, preferably by means of direct copper bonding and direct-bonded copper.

Further preferably, the metallization 11 is also applied to the top side of the substrate 6 in the same step.

The metallization 11 can then be formed into the conductor structures 11a, 11b, 11c by an etching method, for example.

In the first power electronics component 188 shown in FIG. 7, the top side of the bare die layer 14 is also cooled by means of a second heat sink 26. In this way, effective heat dissipation of the bare die layer 14 is made possible from both sides. For this purpose, a second substrate 18 is arranged on the top side of the bare die layer 14, which is provided with metallizations 17, 19 on both sides. The bare die layer 14 is fixedly connected to conductor structures of the metallization 17 of the second substrate 18 and the second substrate 18 is fixedly connected to the second heat sink 26 via the metallization 19. Just like the first heat sink 5, the second heat sink 26 can also be manufactured from a plurality of metal foils 27a-f using a metal layer bonding method. The second heat sink 26 has at least one second cooling channel 37 for cooling the first power electronics component 188.

Since the layer structure on the top side of the bare die layer 14 corresponds to the layer structure on the bottom side of the bare die layer 14, reference is made to the description of the structure provided on the bottom side of the bare die layer 14 with regard to the various possibilities for connecting the layers.

A particularly efficient dissipation of the heat generated by the semiconductor components can be achieved in the first power electronics component 188 shown in FIG. 7 if the cooling channels 35 and 37 are arranged in the immediate vicinity of and at a short distance from the respective substrates 6 and 18. FIG. 2 shows such an embodiment for the first heat sink 5. A “short distance” here means, for example, a distance of less than 50 μm.

FIG. 8 shows an embodiment of the first power electronics component 188, in which the heat dissipation of the semiconductor components on the top side is carried out by means of the second heat sink 26, which is produced by means of a metal layer bonding method. In the embodiment shown in FIG. 8, the first heat sink 5 provided for cooling the bottom side of the semiconductor components is manufactured using an additive manufacturing method. It can be seen that the first heat sink 5 has a first cooling channel 35 through which a cooling flow 36 flows. This cooling flow 36 cools the first cooling wall 50, which is fixedly connected to the metallization 9 mounted on the bottom side of the first substrate 6. It is particularly advantageous if the metallization 9 of the first substrate 6, which was applied to the first substrate 6 using direct-bonded copper, for example, is structured into the first heat sink 5 by means of the additive manufacturing method. Alternatively, the first heat sink 5 could also be produced separately using the additive manufacturing method and then fixedly connected to the metallization 9, for example by soldering, welding or sintering.

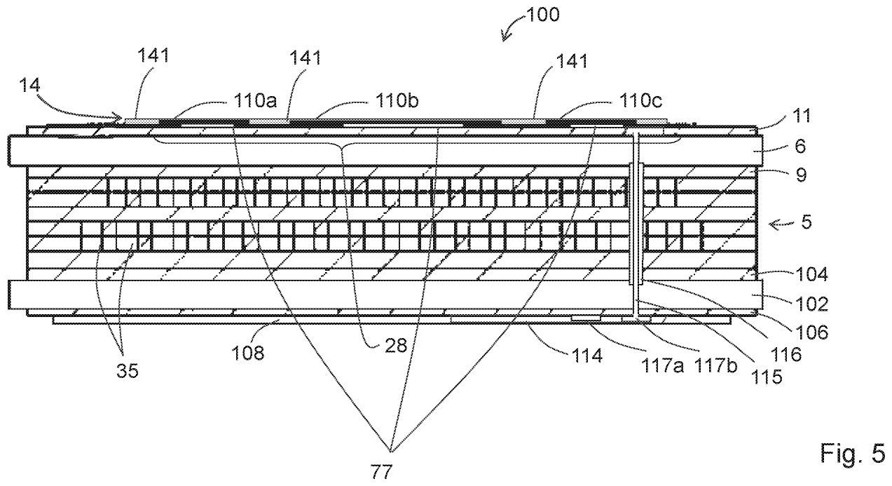

The embodiment shown in FIG. 8 can be designed in such a way that a bare die layer 14, which extends over a large area and comprises a plurality of semiconductor components, is cooled on both sides. Alternatively, the heat sink arrangement shown in FIG. 8 can also be designed in the form of a microcooler for cooling individual semiconductor components or groups of semiconductor components. One such solution is shown in FIG. 5.

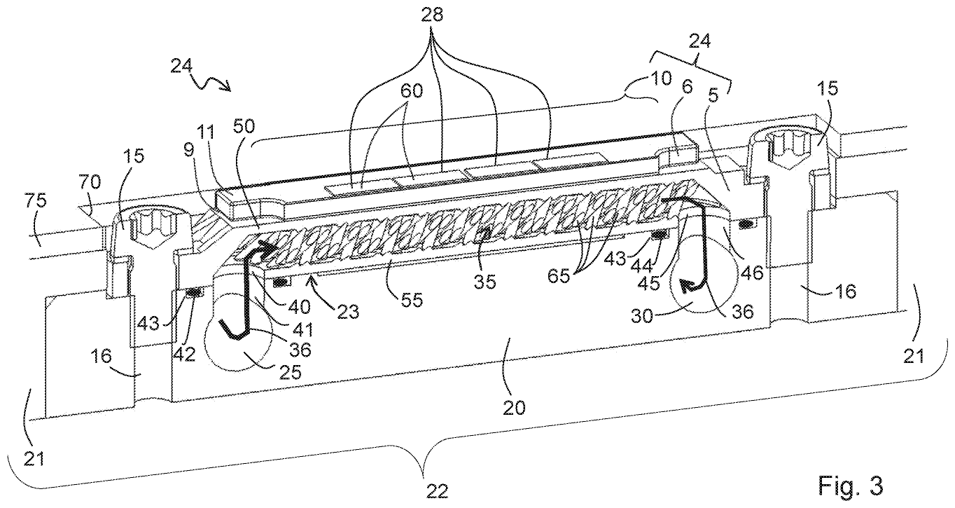

FIG. 3 shows a further embodiment of an electronics assembly 24 as part of a fourth embodiment of a power electronics component 100, 188, 118. The electronics assembly 24 is shown in longitudinal section. The electronics assembly 24 comprises the first heat sink 5 designed to cool an electric unit 10 that is mounted on the first heat sink 5. The electric unit 10 to be cooled can in particular be an electric unit, preferably a semiconductor assembly.

The first heat sink 5 is connected in a detachable manner to a cooling unit 22. In the example shown in the figures, the cooling unit 22 comprises a distribution unit 20 designed here, by way of example, to supply the first heat sink 5 with coolant. Furthermore, the cooling unit 22 here comprises, by way of example, a carrier unit 21 into which the distribution unit 20 is inserted. The cooling unit 22 has a receptacle 23 into which the first heat sink 5 can be inserted in a detachable manner. The first heat sink 5 is then secured to the cooling unit 22 by way of at least one securing means 15, preferably by way of one or more screws. The cooling unit 22 has at least one receiving device 16 for the at least one securing means 15. In order to detach the first heat sink 5 from the cooling unit 22 again, the at least one securing means 15 is first undone. The first heat sink 5, together with the electric unit 10 to be cooled and attached thereto, can then be removed from the receptacle 23 of the cooling unit 22.

In one aspect, the electric unit 10 is mechanically and thermally connected to the first heat sink 5. The electric unit 10 can be connected to the first heat sink 5, for example, by way of one or more soldered connections. Another possibility is to connect the electric unit 10 to the first heat sink 5, for example by way of sintering. Alternatively, the electric unit 10 can be welded to the first heat sink 5. As another, albeit less advantageous, alternative, the electric unit 10 could also be connected to the first heat sink 5 by way of a layer of thermal paste. However, one aspect of the development described here is to implement the connection between the electric unit 10 to be cooled and the first heat sink 5 with as few additional materials and as thin as possible. During the considerations, simulations and tests for this development described here, it was ascertained that this is possible in particular if the heat sink through which the fluid flows is fixedly connected, in particular in a materially bonded manner, to the electric unit 10 to be cooled. This can be achieved, for example, by soldering, sintering, pressing or direct copper bonding (DCB). The term “fixedly” here can mean: “only destructively detachable”. This means using connecting means that cannot be undone even with tools without destroying either the electric unit 10 to be cooled or the first heat sink 5 or both components. It was further recognized that such a solution would only be feasible if a new solution could be found with respect to the interchangeability of the printed circuit board component with electronic components and, in particular, with the electric unit 10 to be cooled mounted on it. This is achieved with the proposed first heat sink 5.

The first heat sink 5 and the electric unit 10, which is mechanically fixedly connected to the first heat sink 5, together form an electronics assembly 24. This electronics assembly 24 can be inserted into the receptacle 23 of the cooling unit 22 and be removed from this receptacle 23 again.

The cooling unit 22 is designed to supply coolant to the first heat sink 5 attached to the cooling unit 22 and to discharge the coolant again after the coolant has flowed through the first heat sink 5. A first flow channel 25 through which coolant can be supplied to the first heat sink 5 can be seen within the cooling unit 22. A second flow channel 30 through which the coolant can be discharged can be seen within the cooling unit 22. The first heat sink 5 has a first cooling channel 35 through which the coolant can flow. A coolant feed 40 is provided at a first end of the first cooling channel 35 and a coolant discharge 45 is provided at the second end of the first cooling channel 35 opposite the first end. The coolant feed 40 and the coolant discharge 45 are fluidically connected to the first cooling channel 35.

The cooling unit 22 comprises a first fluid port 41 that is fluidically connected to the first flow channel 25, and a second fluid port 46 that is fluidically connected to the second flow channel 30. When the first heat sink 5 is inserted and subsequently secured in the receptacle 23, a first fluidic connection is produced between the first fluid port 41 and the coolant feed 40, as well as a second fluidic connection between the second fluid port 46 and the coolant discharge 45.

In order to seal the first fluidic connection, a first sealing ring 42 is arranged in a groove 43 between the cooling unit 22 and the first heat sink 5, wherein the sealing ring 42 entirely surrounds the first fluid port 41. A second sealing ring 44 that entirely surrounds the second fluid port 46 is likewise provided at the second fluid port 46 and is arranged in a groove 43 between the cooling unit 22 and the first heat sink 5. When the at least one securing means 15 is secured, for example when the at least one screw is tightened, the first heat sink 5 is pressed against the first fluid port 41 and the first sealing ring 42 as well as against the second fluid port 46 and the second sealing ring 44. This application of pressure produces a liquid-tight first fluidic connection and a liquid-tight second fluidic connection between the cooling unit 22 and the first heat sink 5.

As shown in FIG. 3, a cooling flow 36 can be produced within the cooling device. The coolant flows from the first flow channel 25 via the first fluid port 41 and the coolant feed 40 into the first cooling channel 35. The coolant flows through the first cooling channel 35 and is discharged again via the coolant discharge 45, the second fluid port 46 and the second flow channel 30.

The first heat sink 5 has a first cooling wall 50 on the side facing the electric unit 10 to be cooled. On the side of the first heat sink 5 facing away from the electric unit 10 to be cooled, the first cooling channel 35 is delimited by a second cooling wall 55, which is opposite the first cooling wall 50. Preferably, the second cooling wall 55 is designed as parallel to the first cooling wall 50.

In the example shown in FIG. 3, the electric unit 10 comprises a semiconductor assembly 28 comprising, for example, an arrangement of transistors 60, which can in particular be designed as bare die semiconductor components. The heat generated during operation of the transistors 60 is dissipated via the coolant flowing in the first cooling channel 35. In order to achieve cooling of the transistors 60 on both sides, a second heat sink can be applied to the top side of the transistors 60. This second heat sink could, for example, be a heat sink manufactured using a metal layer bonding method or a heat sink manufactured using an additive manufacturing method. Such an arrangement is also conceivable for one or more PIN diodes, such as for switching RF power between different paths, or a combination of a transistor and a diode.

In order to improve thermal exchange between the coolant flowing through the first cooling channel 35 and the first heat sink 5, a plurality of cooling pins 65 that extend into the first cooling channel 35 from the first cooling wall 50 and/or from the second cooling wall 55 can be arranged inside the first cooling channel 35. The cooling pins 65 have coolant flowing around them and ensure improved thermal coupling between the first heat sink 5 and the coolant.

FIG. 3 also shows that the electric unit 10 together with the first heat sink 5 arranged thereunder can be arranged within a first recess 70 of a printed circuit board 75.

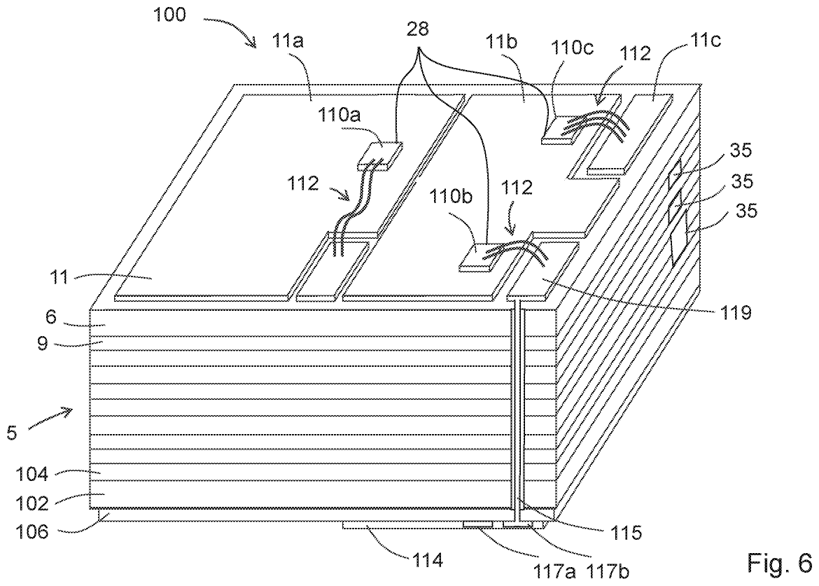

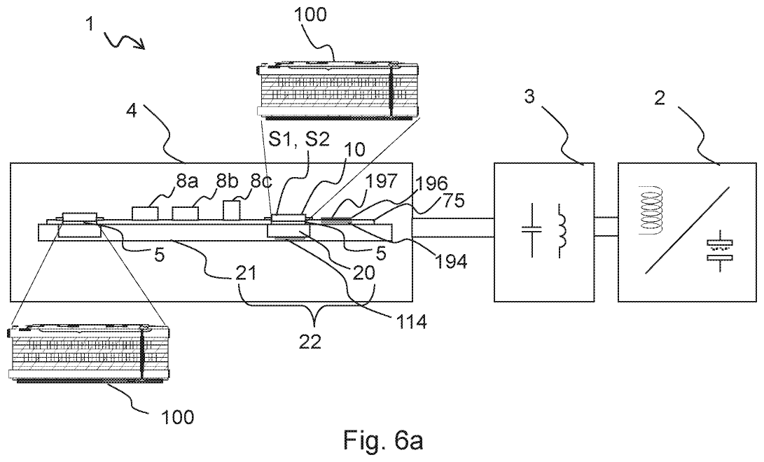

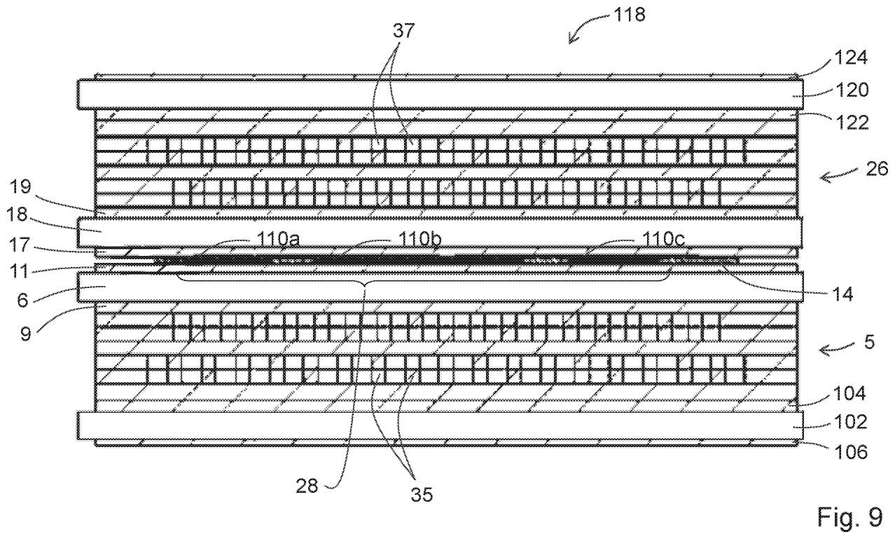

The arrangements shown in FIGS. 7 to 11 can have an electrically insulating additional substrate 102, which has a metallization layer 104, 106 on each of its top and bottom sides, wherein the additional substrate 102 can be mounted on the second side of the first heat sink 5 opposite the first side and/or on the second side of the second heat sink 26 opposite the first side. For example, the second side of the first heat sink 5 can be thermally connected to the metallization layer 104 of the additional substrate 102 facing the first heat sink 5. Alternatively or in addition, for example, the second side of the second heat sink 26 can be thermally connected to the metallization layer of the additional substrate facing the second heat sink 26. This can be seen from a synopsis of FIGS. 6 and 9.

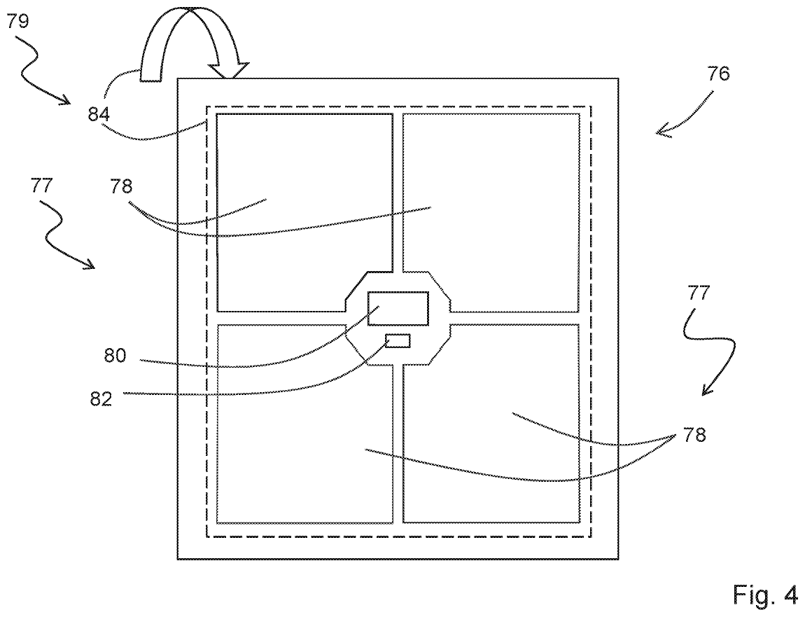

FIG. 4 shows how a bare die component, for example in the form of an IGBT 76, can be electrically contacted. The IGBT 76 has first connections 77 on its first side, in particular designed as four emitter connection surfaces 78, a control connection surface 80 and a test connection surface 82 required for test purposes. On the rear side, the IGBT 76 has a second connection 79, in particular designed as a collector connection surface 84. These connection surfaces can be electrically contacted by the conductor structures 11a-c of the metallizations 11 and/or 17. In particular, the collector connection surface 84 is also directly electrically connected to the connection of the bare die component with the conductor structure 11c. In particular, the emitter connection surfaces 78 are connected to a conductor structure of the opposite metallization 17. It, too, can feature a formation into conductor structures for this purpose, as will be explained in more detail below and in the following figures.

The arrangement can also be reversed, i.e., the collector connection surface 84 can be electrically connected directly to the connection of the bare die component of a conductor structure of the metallization 17 and the emitter connection surfaces 78 can be electrically connected to a conductor structure 11c of the opposite metallization 11.

If the semiconductor components are cooled from both sides, the question arises as to how a control connection of a semiconductor component can be led to the outside. There are various ways of achieving this, which are described above or below, for example in FIGS. 10, 11 and 5.

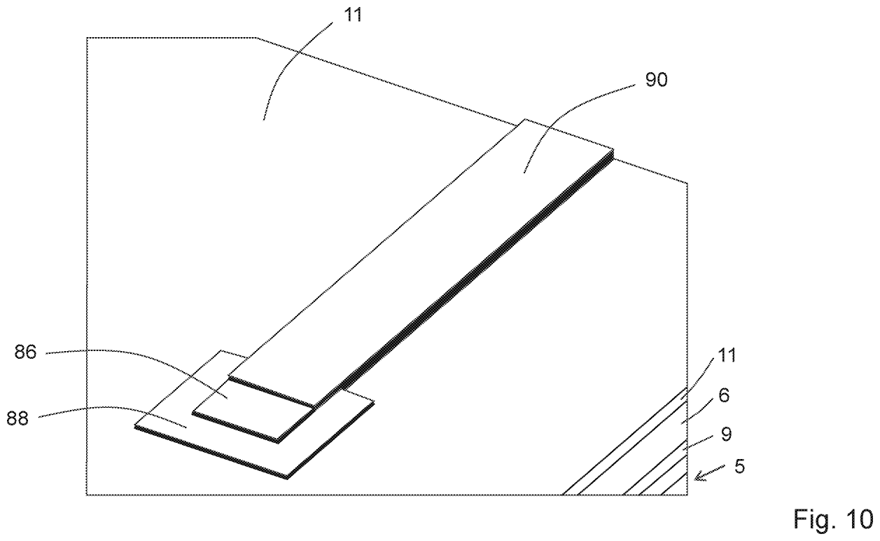

FIG. 10 shows the metallization 11 applied to the first substrate 6. The metallization 11 can, for example, be made of copper, preferably copper coated with NiAu. The coating can serve as a diffusion barrier. An insulating material layer 86 is first applied to the metallization 11, which extends laterally outwards from the location of the respective control connection. A conductor track layer 88 of electrically conductive material is then applied to this insulating material layer 86, which is designed to make electric contact with the control connection of the respective semiconductor component. For this purpose, the insulation material layer 86 can have a recess at the location of the gate connection. A conductor track insulating material layer 90 is then applied to this conductor track layer 88 of electrically conductive material, which also extends laterally outwards from the location of the control connection. The conductor track layer 88 made of electrically conductive material is thus insulated from the metallization 11 by the insulating material layer 86 and from the bare die layer 14 by the conductor track insulating material layer 90. The control connection can be contacted electrically via the conductor track layer 88 made of electrically conductive material, which is routed to the outside.

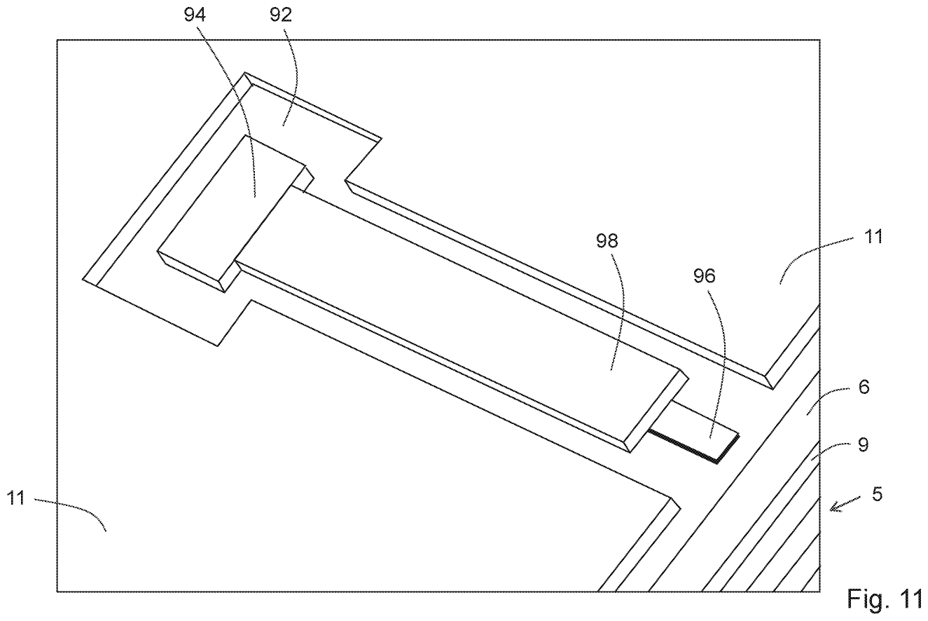

FIG. 11 shows another way in which the control connection of the semiconductor component can be guided laterally to the outside in order to be able to make electric contact with the control connection from the side of the power electronics component. FIG. 11 shows the metallization 11 applied to the first substrate 6. In the first step, the metallization 11 is recessed, e.g., etched away, within the trench-shaped region 92 up to the first substrate 6, wherein an inner region 94 of the metallization 11 remains. This inner region 94 extends laterally outwards from the control connection of the semiconductor component and is insulated from the rest of the metallization 11 by the trench-shaped region 92 extending around the inner region 94. Then, within a partial region 96, the inner region 94 is etched to a certain depth, wherein a portion of the metal remains as a control connection conductor track. A conductor track insulation material layer 98 is then deposited on this partially etched partial region 96. This conductor track insulation material layer 98 insulates the control connection of the semiconductor component, which is routed laterally to the outside, from the bare die layer 14.

According to a further aspect of the development described herein, in at least one of the heat sinks, an additional substrate is arranged on the side of the heat sink facing away from the bare die layer 14 so that the heat sink is arranged in a sandwich structure between two substrates.

FIG. 5 shows a second power electronics component 100 according to the second aspect of the development described herein. FIG. 5 shows that the first substrate 6 is arranged below the bare die layer 14, wherein the metallization 11 of the first substrate 6 is bonded to the bare die layer 14 as described above. The first heat sink 5 is mounted on the side of the first substrate 6 facing away from the bare die layer 14, and an additional substrate 102 is arranged on the side of the first heat sink 5 facing away from the bare die layer 14. The additional substrate 102 has metallizations 104, 106 on both sides. The metallization 104 facing the first heat sink 5 is fixedly connected to the first heat sink 5. The further metallization 106 is arranged on the side of the substrate 6 facing away from the heat sink 5 and can be designed like a previously described conductor structure for receiving electronic components, in particular semiconductor components. This further substrate 102 can increase the stability of the heat sink 5. In addition, the further metallization 106 on the side of the substrate 6 facing away from the heat sink 5 offers the possibility of arranging drivers and/or measurement electronics with very short electric paths to the power components of the bare die layer 14.

The first heat sink 5 is thus arranged in a sandwich structure between the first substrate 6 and the additional substrate 102. The substrates 6 and 102 are preferably made of ceramic, and therefore this sandwich structure results in an additional mechanical stabilization of the first heat sink 5. A further advantage is that one or more semiconductor components can be arranged on the metallization 106, which is located on the side of the additional substrate 102 facing away from the first heat sink 5, for example in a further bare die layer 108. The additional substrate 102 can therefore be used, for example, to accommodate driver and control circuits, such as control electronics 114 for the actual power electronics. In this case, one or more vias 115 extending through the first heat sink 5 can be used to form electric connections between the semiconductor components, for example the control electronics 114, which can be part of the further bare die layer 108, and the semiconductor components 110a-c of the bare die layer 14 arranged on the first substrate 6. At least one connection 117a of the control electronics 114 can be thermally and electrically connected to at least one region of the further metallization layer 106 facing the control electronics 114. At least one further connection 117b of the control electronics 114 can be electrically connected to a connection 119 of the semiconductor assembly 28 via at least one via 115, which extends through the first heat sink 5, in particular in a manner insulated therefrom.

The second power electronics component 100 shown in FIG. 5 is shown again in a diagonal view in FIG. 6. FIG. 6 shows the first substrate 6 with the metallizations 9 and 11 on both sides, the additional substrate 102 with the two metallizations 104 and 106 and the first heat sink 5 arranged between them. Semiconductor components 110a, 110b, 110c, which are part of the bare die layer 14, are mounted on the top side of the metallization 11. On the top side of the second power electronics component 100, undulating connecting lines 112, in particular designed as bonding wires, can also be seen, which are provided to produce electric connections between the semiconductor components 110a, 110b, 110c and the conductor structures on the metallization 11 by means of wire bonding.

On the side of the additional substrate 102 facing away from the first heat sink 5, further semiconductor components such as, for example, control electronics 114 are arranged on the metallization 106, which can be connected to the semiconductor components 110a, 110b, 110c on the top side of the second power electronics component 100, for example via a through-connection, also referred to as a “via” 115.

A via insulation 116 can be provided in the region of the heat sink 5 to protect the through-connection from electric contact with the heat sink 5.

The first cooling channels 35 extend inside the first heat sink 5.

The power electronics component 100 shown in FIG. 5 can optionally have a second heat sink 26, such as that shown in FIG. 7 or FIG. 9. This second heat sink 26 can be thermally connected to the metallization layer 19 of the second substrate 18 facing away from the semiconductor assembly 28. In this regard, the second heat sink 26 can have at least one second cooling channel 37 through which coolant can flow.

FIG. 6a shows an industrial process assembly 1, preferably a plasma process assembly or a heating assembly. The industrial process assembly 1 has: an electric power converter 4, a load 2, preferably a plasma process or heating process, e.g., an induction or microwave heating process, wherein the load 2 is electrically connected to the electric power converter 4, such that the electric power converter 4 can supply the load 2 with the required electric power, optionally an additional adaptation unit 3 which is connected between the power converter 4 and the load 2.

The power converter 4 has: two of the second power electronics components 100, as previously described, for example, in the description of FIG. 6 and previously and subsequently described, for example, in the description of FIG. 6, a cooling unit 22, which, as described above and below, has one or more distribution units 20 and a carrier unit 21, a printed circuit board 75, a unit 10 to be cooled, in particular an electric unit, preferably a semiconductor assembly, preferably having a power semiconductor component, further electronic components 8a, 8b, 8c, wherein the further electronic components 8a, 8b, 8c and the unit 10 to be cooled are arranged on or at a printed circuit board 75 and are connected to electric contacts, wherein the unit 10 to be cooled is fixedly connected, in particular by means of material bonding, to the heat sink 5.85.

Two power semiconductor components, in particular transistors S1, S2, which each have a first and a second power terminal and a control connection, wherein both transistors S1, S2 can be connected to one of their power terminals in order to form a series circuit, are arranged here on or at the printed circuit board 75 as the unit 10 to be cooled. A direct current or direct voltage can be connected to the remaining power terminals. Control electronics 114 can be connected to the control connections of the power semiconductor components.

A power transformer 197 having a primary winding 196 and a secondary winding 194 is also arranged on the printed circuit board 75 here. The primary winding 196 and the secondary winding 194 of the power transformer 197 are each designed here as planar conductor tracks, which are arranged in different layers of the printed circuit board 75. The printed circuit board has a thermal connection with the cooling unit 22.

Here, the thermal connection with the cooling unit 22 can have a thermally conductive compensation layer which is fixedly connected with its first face to the first face of the printed circuit board 75 and a connection layer which is fixedly connected with its first face to the second face of the thermally conductive compensation layer and fixedly connected with its second face to the heat distributor.

FIG. 9 shows a third power electronics component 118, which has a power electronics component of the type shown in FIG. 5 on both the top side and the bottom side of the bare die layer 14. The first substrate 6 with the two metallizations 9 and 11, the heat sink and the additional substrate 102 with the two metallizations 104 and 106 are arranged on the bottom side of the bare die layer 14. The second substrate 18 with the metallizations 17 and 19, the second heat sink 26 and the additional substrate 120 with the metallizations 122 and 124 are arranged on the top side of the bare die layer 14. First cooling channels 35 are provided in the first heat sink 5 and second cooling channels 37 are provided in the second heat sink 26, through which coolant can flow.

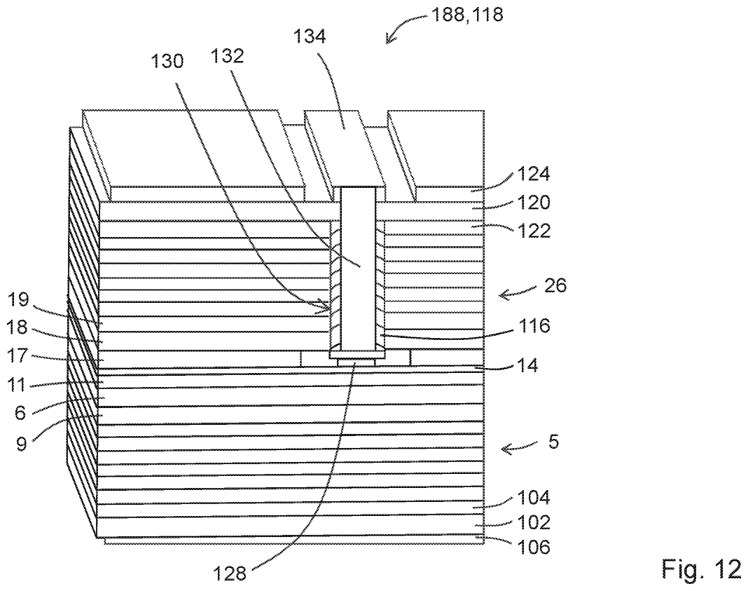

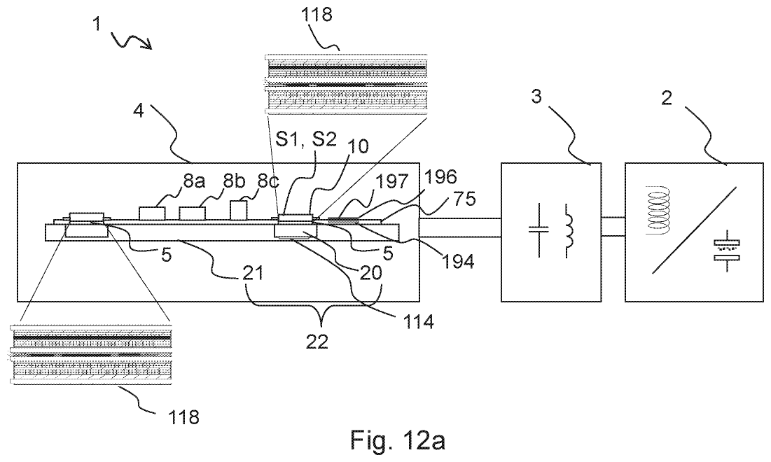

FIG. 12a shows an industrial process assembly 1, preferably a plasma process assembly or a heating assembly. The industrial process assembly 1 has: an electric power converter 4, a load 2, preferably a plasma process or heating process, e.g., an induction or microwave heating process, wherein the load 2 is electrically connected to the electric power converter 4, such that the electric power converter 4 can supply the load 2 with the required electric power, optionally an additional adaptation unit 3 which is connected between the power converter 4 and the load 2.

The power converter 4 has: two of the first power electronics components 118, as previously or subsequently described, for example, in the description of FIGS. 9, 12, a cooling unit 22, which, as described above and below, has one or more distribution units 20 and a carrier unit 21, a printed circuit board 75, a unit 10 to be cooled, in particular an electric unit, preferably a semiconductor assembly, preferably having a power semiconductor component, further electronic components 8a, 8b, 8c, wherein the further electronic components 8a, 8b, 8c and the unit 10 to be cooled are arranged on or at a printed circuit board 75 and are connected to electric contacts, wherein the unit 10 to be cooled is fixedly connected, in particular by means of material bonding, to the heat sink 5.85.

Two power semiconductor components, in particular transistors S1, S2, which each have a first and a second power terminal and a control connection, wherein both transistors S1, S2 can be connected to one of their power terminals in order to form a series circuit, are arranged here on or at the printed circuit board 75 as the unit 10 to be cooled. A direct current or direct voltage can be connected to the remaining power terminals. Control electronics 114 can be connected to the control connections of the power semiconductor components.

A power transformer 197 having a primary winding 196 and a secondary winding 194 is also arranged on the printed circuit board 75 here. The primary winding 196 and the secondary winding 194 of the power transformer 197 are each designed here as planar conductor tracks, which are arranged in different layers of the printed circuit board 75. The printed circuit board has a thermal connection with the cooling unit 22.

Here, the thermal connection with the cooling unit 22 can have a thermally conductive compensation layer which is fixedly connected with its first face to the first face of the printed circuit board 75 and a connection layer which is fixedly connected with its first face to the second face of the thermally conductive compensation layer and fixedly connected with its second face to the heat distributor.

FIG. 12 shows another possibility of how a control connection 128 of a semiconductor component can be contacted from the outside in a third power electronics component 188, 118 with cooling of the semiconductor components on both sides. In the embodiment shown in FIG. 12, the control connection 128 of the semiconductor component is electrically contacted from the top side of the third power electronics component 118. FIG. 12 shows the bare die layer 14. The first substrate 6 with its two metallizations 9 and 11 and the first heat sink 5 are arranged on the bottom side of the bare die layer 14. The second substrate 18 with its metallizations 17 and 19 and the second heat sink 26 are mounted on the top side of the bare die layer 14. Furthermore, in FIG. 12, the additional substrate 102 is mounted on the bottom side of the first heat sink 5, which is provided with metallizations 104, 106 on both sides. The additional substrate 120, which has the metallizations 122 and 124, is arranged on the top side of the second heat sink 26.

A hole 130 is provided for making electric contact with the control connection 128, which extends from the top side of the third power electronics component 118 through the second heat sink 26 to the control connection 128. A pin 132 of conductive material, preferably copper or another metal, is introduced into the hole 130 such that the pin 130 makes electric contact with the control connection 128. In this way, a via is provided that leads the control connection 128 to the outside through the second heat sink 26. Optionally, a connection surface 134 can be provided on the top side of the power electronics component above the additional substrate 120, wherein the connection surface 134 is electrically connected to the control connection 128 via the pin 132.

A via insulation 116 can be provided in the region of the second heat sink 26 to protect the through-connection from electric contact with the second heat sink 26.

The features disclosed in the above description, the claims, and the drawings may be important both individually and in any combination for implementing the various configurations of the development described herein.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power electronics component for an electric power converter for an industrial process assembly designed to supply a load, the component comprising:
an electrically insulating substrate comprising a top-side metallization layer on a top side and a bottom-side metallization layer on a bottom side, wherein the top-side metallization layer is divided into at least three electrically isolated regions of a conductor structure;
a semiconductor assembly mounted on the substrate, comprising:
at least two semiconductor components connected in series, at least one of which is a controllable power semiconductor component, wherein the two semiconductor components connected in series each comprise:
at least one first connection configured as a collector connection surface or source connection surface, thermally and electrically connected to at least one first region of the conductor structure, and
at least one second connection configured as an emitter connection surface or drain connection surface, electrically connected via a plurality of connecting lines to a second connection surface of another semiconductor component and/or to one of the regions of the conductor structure; and
a heat sink arranged on the substrate, wherein a first side facing the substrate is thermally connected to the bottom-side metallization layer of the substrate, which bottom-side metallization layer faces away from the semiconductor assembly,
wherein the heat sink is monolithically constructed, is fixedly connected to the bottom-side metallization layer, and comprises a cooling channel for guiding a cooling flow.

2. The component according to claim 1, wherein the semiconductor components are designed as bare die semiconductor components and are thermally and electrically connected directly with their respective at least one first connection to one of the regions of the conductor structure.

3. The component according to claim 1, wherein two semiconductor components of the at least two semiconductor components connected in series are arranged on two of three regions of the conductor structure, a third region of the conductor structure is free of the semiconductor components, and only has contacting connections.

4. The component according to claim 1, wherein the semiconductor assembly is an AC converter assembly comprising a semiconductor switching unit comprising two transistors, wherein the transistors are electrically connected to one another at at least one power terminal.

5. The component according to claim 1, wherein the semiconductor assembly comprises: an intermediate circuit capacitor C1, arranged close to power terminals of the transistors with connecting leads having a length of less than or equal to 20 mm.

6. The component according to claim 1, wherein the semiconductor assembly comprises: a positive contact connection device and a negative contact connection device, in each case configured to contact a connection point on a printed circuit board or a mechanical connecting line, such as a copper line,
wherein the positive contact connection device is directly electrically connected to the positive connection point of one of the regions of the conductor structure.

7. The component according to claim 1, wherein a plurality of semiconductor switching units are arranged on the heat sink.

8. The component according to claim 1, further comprising: an electrically insulating additional substrate comprising an additional metallization layer on each of its top and bottom sides, wherein the additional substrate is mounted on the second side of the heat sink opposite the first side, and wherein the second side of the heat sink is thermally connected to the additional metallization layer of the additional substrate facing the heat sink.

9. The component according to claim 1, wherein the component comprises control electronics which are arranged on a side of the additional substrate facing away from the heat sink, wherein at least one connection of the control electronics is thermally and electrically connected to at least one region of the additional metallization layer facing the control electronics.

10. The component according to claim 9, wherein at least one further connection of the control electronics is electrically connected to a connection of the semiconductor assembly via at least one via, which extends through the heat sink.

11. The component according to claim 1, wherein the substrate and/or an additional substrate is one of the following: a ceramic substrate, a direct-bonded copper substrate, an insulated metal brazed substrate, an active metal brazed substrate, or a thick-film substrate.

12. The component according to claim 1, further comprising:
an electrically insulating second substrate which is mounted on the semiconductor assembly and has a second metallization layer on each of its top and bottom sides, wherein the semiconductor assembly comprises at least one second connection which is thermally and electrically connected to at least a second region of the second metallization layer of the second substrate facing the semiconductor assembly,
a second heat sink which is thermally connected to the second metallization layer of the second substrate facing away from the semiconductor assembly, wherein the second heat sink has at least one second cooling channel through which coolant can flow.

13. The component according to claim 12, wherein the second heat sink is implemented at least partially in the form of a layered structure of thermally connected metal foils.

14. The component according to claim 12, wherein the substrate and/or the second substrate is one of the following: a ceramic substrate, a direct-bonded copper substrate, an insulated metal brazed substrate, an active metal brazed substrate, or a thick-film substrate.

15. The component according to claim 1, wherein the semiconductor assembly comprises a bare die layer, wherein the bare die layer comprises one or more of the at least two semiconductor components.

16. The component according to claim 1, wherein the heat sink is implemented at least partially in the form of a layered structure of thermally connected metal foils.

17. The component according to claim 16, wherein the heat sink comprises at least the cooling channel through which coolant can flow, wherein the at least one cooling channel is implemented in the form of at least one recess provided in the metal foils.

18. The component according to claim 1, wherein the heat sink is produced at least partially by means of an additive manufacturing method.

19. The component according to claim 1, wherein the heat sink comprises a coolant feed and a coolant discharge, both of which are fluidically connected to the cooling channel, wherein the heat sink is configured to be mounted in a detachable manner on a cooling unit comprising a first fluid port and a second fluid port and that, when the heat sink is mounted on the cooling unit, a first fluidic connection is established between the coolant feed of the heat sink and the first fluid port of the cooling unit and a second fluidic connection is established between the coolant discharge of the heat sink and the second fluid port of the cooling unit.

20. The component according to claim 1, wherein the substrate is connected to the heat sink at a cooling wall in a materially bonded manner,
wherein the power electronics component is configured such that, during operation, the coolant is guided through the cooling channel at a predetermined operating pressure,
wherein a distance between the cooling channel and the cooling wall is selected to be so small that the heat sink cannot ensure sufficient form stability and/or tightness at the predetermined operating pressure of 3 bar or more overpressure relative to ambient pressure, without the substrate connected to it in a materially bonded manner, and
wherein the substrate and the materially bonded connection to the heat sink on the cooling wall are configured such that the power electronics component can ensure this sufficient form stability and tightness.

21. The component according to claim 1, wherein at least one control connection and at least one first power terminal are arranged on a first side of the semiconductor assembly, and at least one second power terminal is arranged on a second side of the semiconductor assembly.

22. The component according to claim 1, wherein the top-side metallization layer facing a first side of the semiconductor assembly has at least one first metallization region for making electric contact with at least one control connection of the semiconductor assembly and at least one second metallization region for making electric contact with at least one first power terminal of the semiconductor assembly, wherein the at least one first metallization region and the at least one second metallization region are electrically isolated from one another, and wherein at least one first metallization region is guided to a side of the component and is configured to be electrically contacted from the side of the component.

23. The component according to claim 1, wherein an electric contacting of at least one control connection of the semiconductor assembly is achieved via at least one via extending through the heat sink.

24. A method for joining a power electronics component, comprising:
arranging a top-side metallization layer on a top side of an electrically insulating substrate, wherein the top-side metallization layer is divided into at least three electrically isolated regions of a conductor structure;
arranging a bottom-side metallization layer on a bottom side of the substrate;
arranging a semiconductor assembly on the substrate, wherein the semiconductor assembly comprises at least two semiconductor components connected in series;
establishing at least one thermal and electric connection between the two semiconductor components connected in series and at least a first region of the top-side metallization layer of the substrate facing the semiconductor assembly,
establishing at least one electric connecting line from a second connection of the two semiconductor components connected in series to at least one second connection surface of another semiconductor component or to one of the regions of the conductor structure,
constructing a monolithically constructed heat sink with a cooling channel for guiding a cooling flow,
arranging the monolithically constructed heat sink on the substrate, and in the process, establishing a thermal and electric connection between a first side of the heat sink facing the substrate and the bottom-side metallization layer of the substrate facing away from the semiconductor assembly.

25. The method according to claim 24, further comprising:
arranging a positive contact connection device at a region of the conductor structure with a direct electric connection to the region of the conductor structure using ultrasonic welding; and
arranging a negative contact connection device at the region of the conductor structure with the direct electric connection to the region of the conductor structure using ultrasonic welding.

26. The method according to claim 24, further comprising:
arranging an electrically insulating additional substrate, comprising a metallization layer on each of a top side and a bottom side, on a second side of the heat sink opposite the first side; and
establishing a thermal and electric connection between the second side of the heat sink and the metallization layer of the additional substrate facing the heat sink.

27. The method according to claim 24, wherein the heat sink is produced at least partially by means of a metal layer bonding method.

28. The method according to claim 24, wherein the bottom-side metallization layer of the substrate and metal foils of the heat sink are joined in one process.

29. The method according to claim 24, further comprising:
arranging an electrically insulating second substrate, comprising a metallization layer on each of a top side and a bottom side, on the semiconductor assembly;
establishing at least one thermal and electric connection between at least a second connection of the semiconductor assembly and at least a second region of the metallization layer of the second substrate facing the semiconductor assembly;
when arranging the heat sink on the substrate, providing the cooling channel through which coolant can flow;
arranging a second heat sink on the second substrate, wherein the second heat sink comprises at least one second cooling channel through which coolant can flow; and
establishing a thermal and electric connection between the second heat sink and the metallization layer of the second substrate facing away from the semiconductor assembly.

30. An electric power converter for an industrial process assembly, comprising a power electronics component according to claim 1 configured to generate an RF output power.

31. The electric power converter according to claim 30, wherein the power electronics component further comprises:
two transistors, which each have a first and a second power terminal and a control connection, wherein both transistors are connected to one of their power terminals in order to form a series circuit, wherein a direct current or direct voltage is connected to remaining power terminals, wherein further control electronics are provided which are connected to the control connections of the two transistors, and the control electronics are configured to control the transistors to generate an RF power and transfer from a first conductive state to a second conductive state, wherein the conductivity of the two states is different.

32. The electric power converter according to claim 30, wherein a power transformer, comprising a primary winding and a secondary winding, is arranged on a printed circuit board, wherein the primary winding is connected to at least one power terminal of transistors, wherein the primary winding and the secondary winding of the power transformer are each designed as planar conductor tracks which are arranged in different layers of the printed circuit board, and the printed circuit board has a thermal connection to the cooling unit.
